(19) United States
(12) Patent Application Publication
(10) Pub. No.: US 2026/0068300 A1
(43) Pub. Date: Mar. 5, 2026

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Jer-Fu WANG, Taipei City (TW); Shu-Jui CHANG, Hsinchu County (TW); Chih-Sheng CHANG, Hsinchu City (TW); Iuliana RADU, Hsinchu County (TW)

(73) Assignee: TAIWAN SEMICONDUCTOR MANUFACTURING COMPANY, LTD., Hsinchu (TW)

(21) Appl. No.: 18/819,599

(22) Filed: Aug. 29, 2024

(51) Int. Cl. H01L 27/092; H01L 21/8238; H01L 29/06; H01L 29/423; H01L 29/49; H01L 29/66; H01L 29/775; H01L 29/786

(52) U.S. Cl. CPC H10D 84/85; H10D 30/014; H10D 30/43; H10D 30/6735; H10D 30/6739; H10D 30/6757; H10D 62/121; H10D 64/017; H10D 84/0181; H10D 84/038

(57) ABSTRACT

A semiconductor device includes first and second transistors. The first transistor includes first semiconductor channel layers and a first gate structure. The first gate structure includes a first interfacial layer, a first high-k dielectric layer, and a first filling metal. A region of the first interfacial layer close to the first high-k dielectric layer has a higher concentration of a first metal element than a region of the first interfacial layer away from the first high-k dielectric layer. The second transistor includes second semiconductor channel layers and a second gate structure. The second gate structure includes a second interfacial layer, a second high-k dielectric layer, and a second filling metal. A region of the second high-k dielectric layer close to the second filling metal has a higher concentration of the first metal element than a region of the second high-k dielectric layer away from the second filling metal.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (e.g., the number of interconnected devices per chip area) has generally increased while geometry size (e.g., the smallest component (or line) that can be created using a fabrication process) has decreased. This scaling down process generally provides benefits by increasing production efficiency and lowering associated costs. However, scaling down has also led to challenges that may not have been presented by previous generations at larger geometries.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 12D show cross-sectional views of intermediate structures at respective stages during an example method for forming a semiconductor device in accordance with some embodiments.

FIG. 13 shows distributions of metal atoms in different metal gate structures in accordance with some embodiments.

FIGS. 14 to 15B show cross-sectional views of intermediate structures at respective stages during an example method for forming a semiconductor device in accordance with some embodiments.

FIG. 16 shows distributions of metal atoms in different metal gate structures in accordance with some embodiments.

FIGS. 17 to 18B show cross-sectional views of intermediate structures at respective stages during an example method for forming a semiconductor device in accordance with some embodiments.

FIG. 19 shows distributions of metal atoms in different metal gate structures in accordance with some embodiments.

FIGS. 20 to 22B show cross-sectional views of intermediate structures at respective stages during an example method for forming a semiconductor device in accordance with some embodiments.

FIGS. 23 to 25B show cross-sectional views of intermediate structures at respective stages during an example method for forming a semiconductor device in accordance with some embodiments.

FIGS. 26 to 31C show cross-sectional views of intermediate structures at respective stages during an example method for forming a semiconductor device in accordance with some embodiments.

FIGS. 32A to 34C show cross-sectional views of intermediate structures at respective stages during an example method for forming a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

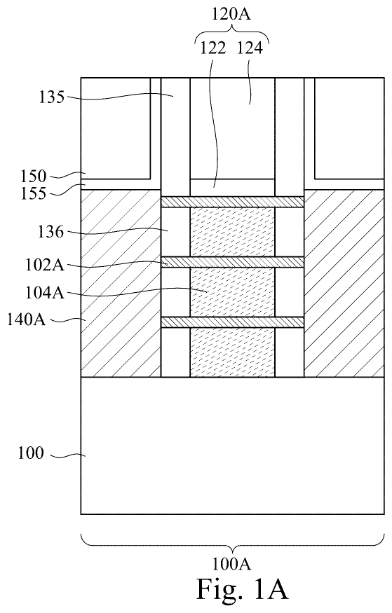

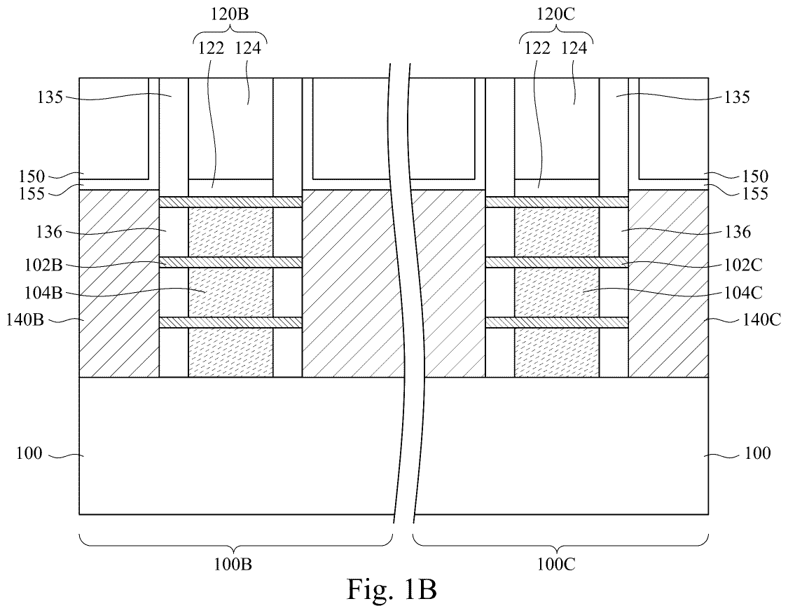

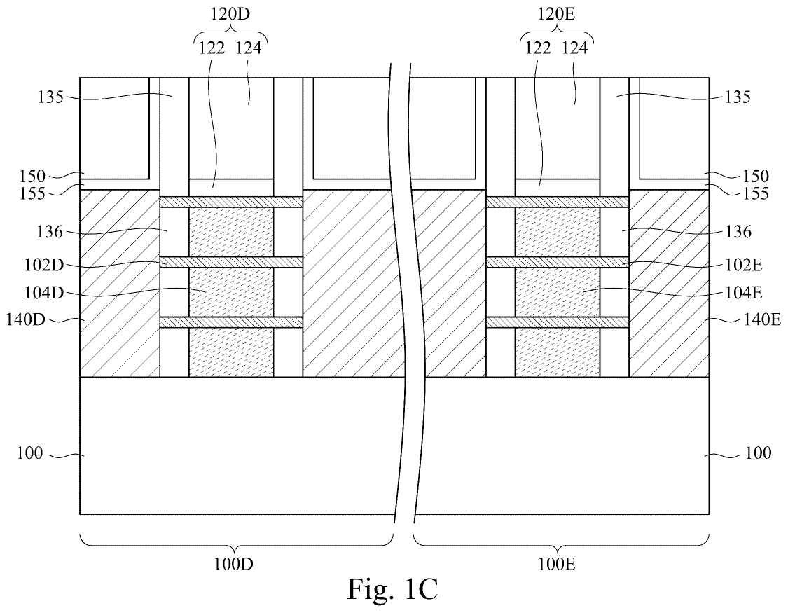

FIGS. 1A to 12D are cross-sectional views of intermediate structures at respective stages during an example method for forming a semiconductor device in accordance with some embodiments. Although FIGS. 1A to 12D are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIGS. 1A, 1B, and 1C. Shown there is a substrate 100. The substrate 100 includes different regions 100A, 100B, 100C, 100D, and 100E. In some embodiments, the region 100A of the substrate 100 may be a P-type region where a P-type device is formed thereon, or may be an N-type region where an N-type device is formed thereon. The regions 100B and 100C may be N-type regions where N-type devices are formed thereon. The regions 100D and 100E may be P-type regions where P-type devices are formed thereon.

The substrate 100 generally include crystalline semiconductor material, such as silicon, but may include one or more other semiconductor materials such as germanium, silicon-germanium alloys, compound semiconductors (e.g., GaAs, AlAs, InAs, GaN, AlN, and the like), or their alloys (e.g., GaxAl₁₋ₓAs, GaₓAl₁₋ₓN, InₓGa₁₋ₓAs and the like), or combinations thereof.

With respect to the region 100A of the substrate 100 in FIG. 1A. A stack of alternating semiconductor layers 102A and sacrificial layers 104A are formed over the region 100A of the substrate 100. A dummy gate structure 120A is formed over the stack of alternating semiconductor layers 102A and sacrificial layers 104A. The dummy gate structure 120A may include a dummy gate dielectric 122 and a dummy gate electrode 124 over the dummy gate dielectric 122. Gate spacers 135 are formed on opposite sidewalls of the dummy gate structure 120A. Inner spacers 136 are on opposite sides of the sacrificial layers 104A. Source/drain epitaxial structures 140A are on opposite sides of the dummy gate structure 120A and in contact with opposite ends of each of the semiconductor layers 102A. A contact etch stop layer 155 and an interlayer dielectric (ILD) layer 150 are formed over the source/drain epitaxial structures 140A and laterally surrounding the dummy gate structure 120A.

With respect to the regions 100B and 100C of the substrate 100 in FIG. 1B. A stack of alternating semiconductor layers 102B and sacrificial layers 104B are formed over the region 100B of the substrate 100, and a stack of alternating semiconductor layers 102C and sacrificial layers 104C are formed over the region 100C of the substrate 100. A dummy gate structure 120B is formed over the stack of alternating semiconductor layers 102B and sacrificial layers 104B, and a dummy gate structure 120C is formed over the stack of alternating semiconductor layers 102C and sacrificial layers 104C. The dummy gate structures 120B and 120C each may include a dummy gate dielectric 122 and a dummy gate electrode 124 over the dummy gate dielectric 122. Gate spacers 135 are formed on opposite sidewalls of the dummy gate structures 120B and 120C. Inner spacers 136 are on opposite sides of the sacrificial layers 104B and 104C. Source/drain epitaxial structures 140B are on opposite sides of the dummy gate structure 120B and in contact with opposite ends of each of the semiconductor layers 102B, and source/drain epitaxial structures 140C are on opposite sides of the dummy gate structure 120C and in contact with opposite ends of each of the semiconductor layers 102C. A contact etch stop layer 155 and an interlayer dielectric (ILD) layer 150 are formed over the source/drain epitaxial structures 140B and 140C, and laterally surrounding the dummy gate structures 120B and 120C.

With respect to the regions 100D and 100E of the substrate 100 in FIG. 1C. A stack of alternating semiconductor layers 102D and sacrificial layers 104D are disposed over the region 100D of the substrate 100, and a stack of alternating semiconductor layers 102E and sacrificial layers 104E are disposed over the region 100E of the substrate 100. A dummy gate structure 120D is formed over the stack of alternating semiconductor layers 102D and sacrificial layers 104D, and a dummy gate structure 120E is formed over the stack of alternating semiconductor layers 102E and sacrificial layers 104E. The dummy gate structures 120D and 120E each may include a dummy gate dielectric 122 and a dummy gate electrode 124 over the dummy gate dielectric 122. Gate spacers 135 are formed on opposite sidewalls of the dummy gate structures 120D and 120E. Inner spacers 136 are on opposite sides of the sacrificial layers 104D and 104E. Source/drain epitaxial structures 140D are on opposite sides of the dummy gate structure 120D and in contact with opposite ends of each of the semiconductor layers 102D, and source/drain epitaxial structures 140E are on opposite sides of the dummy gate structure 120E and in contact with opposite ends of each of the semiconductor layers 102E. A contact etch stop layer 155 and an interlayer dielectric (ILD) layer 150 are formed over the source/drain epitaxial structures 140D and 140E, and laterally surrounding the dummy gate structures 120D and 120E.

In some embodiments, the semiconductor layers 102A, 102B, 102C, 102D, and 102E are made of a same semiconductor material, and may act as channel layers of the respective semiconductor devices. For example, the semiconductor layers 102A, 102B, 102C, 102D, and 102E may be made of pure silicon layers that are substantially free of germanium. In some embodiments, the semiconductor layers 102A, 102B, 102C, 102D, and 102E may also be substantially pure silicon layers, for example, with a germanium percentage lower than about 1 percent. The sacrificial layers 104A, 104B, 104C, 104D, and 104E may be made of silicon germanium. For example, the germanium percentage (atomic percentage concentration) of the sacrificial layers 104A, 104B, 104C, 104D, and 104E may be in a range from about 20 percent and about 60 percent. In some embodiments, the semiconductor layers 102A to 102E, and the sacrificial layers 104A to 104E may be deposited using suitable deposition process, such as selective epitaxial growth (SEG), chemical vapor deposition (CVD), molecular beam epitaxy (MBE), or other suitable process(es). In some embodiments, the sacrificial layers 104A to 104E may be removed during a replacement gate (RPG) process. The sacrificial layers 104A to 104E may also be referred to as sacrificial semiconductor layers.

In some embodiments, the dummy gate structures 120A, 120B, 120C, 120D, and 120E are made of same materials. For example, the dummy gate dielectric 122 may be, for example, silicon oxide, silicon nitride, a combination thereof, or the like, and may be deposited or thermally grown according to acceptable techniques. The dummy gate electrode 124 may be a conductive or non-conductive material and may be selected from a group including amorphous silicon, polycrystalline-silicon (polysilicon), polycrystalline silicon-germanium (poly-SiGe), metallic nitrides, metallic silicides, metallic oxides, and metals.

In some embodiments, the gate spacers 135 and the inner spacers 136 may include silicon oxide, silicon nitride, silicon oxynitride, the like, or combinations thereof. The gate spacers 135 and the inner spacers 136 may be deposited using techniques such CVD, ALD, or the like.

In some embodiments, the source/drain epitaxial structures 140A may be N-type epitaxial structures or P-type epitaxial structures. The source/drain epitaxial structures 140B and 140C may be N-type epitaxial structures. The source/drain epitaxial structures 140D and 140e may be P-type epitaxial structures. In some embodiments, the N-type epitaxial structures may include SiAs, SiC, SiCP, the like, or a combination thereof. The N-type epitaxial structures may be doped with N-type dopants, such as phosphorus (P), arsenic (As), or antimony (Sb), or the like. The P-type epitaxial structures may include SiGe, SiGeB, GeB, SiGeSnB, the like, or a combination thereof. The P-type epitaxial structures may be doped with P-type dopants, such as boron (B), gallium (Ga), indium (In), aluminium (Al), or the like.

In some embodiments, the CESL 155 may be a dielectric layer including silicon nitride, silicon oxynitride or other suitable materials. In some embodiments, the ILD layer 150 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The CESL 155 and the ILD layer 150 can be formed using, for example, CVD, ALD or other suitable techniques.

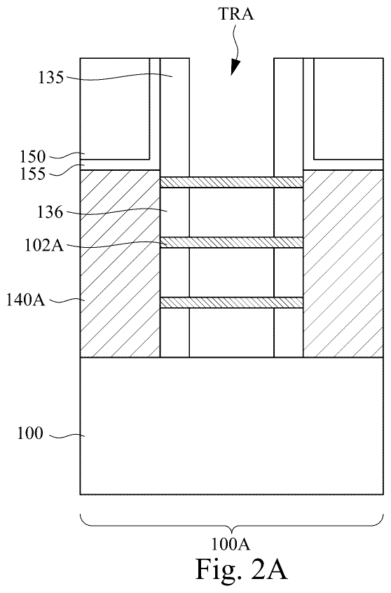

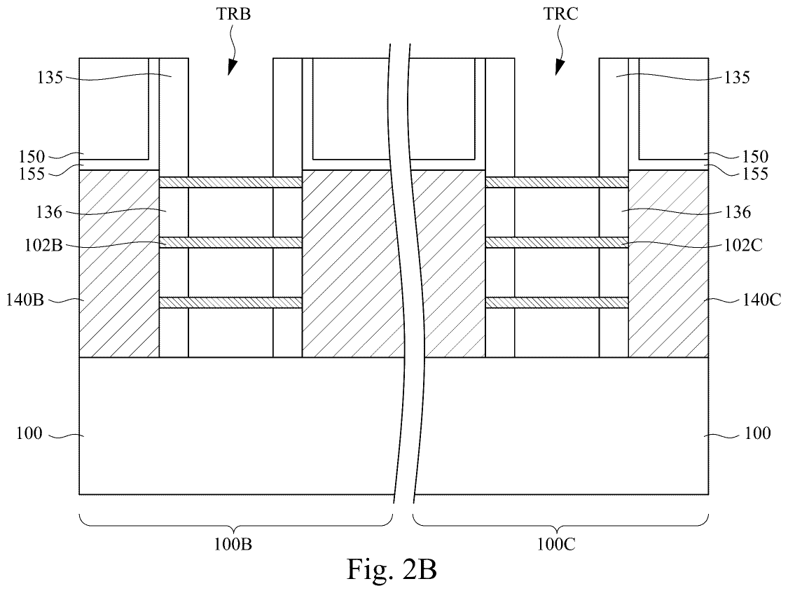

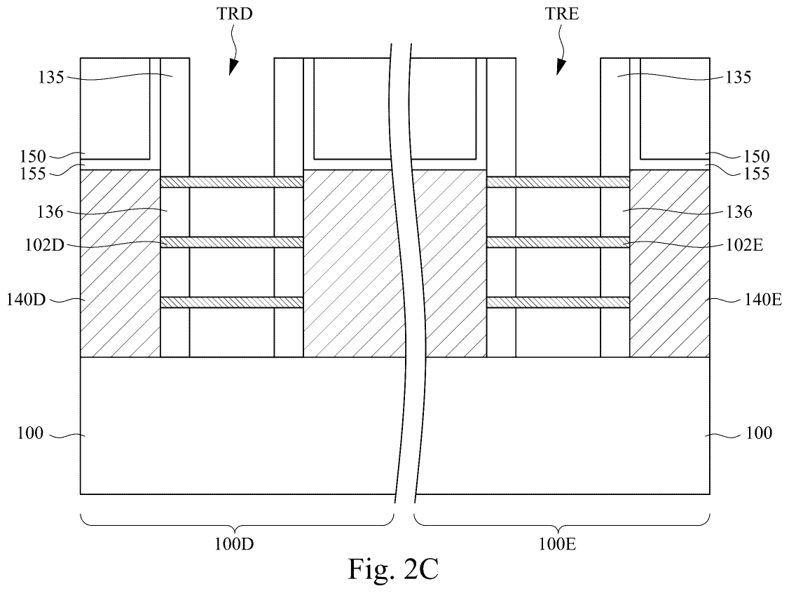

Reference is made to FIGS. 2A, 2B, and 2C. The dummy gate structures 120A to 120E are removed, so as to form gate trenches TRA, TRB, TRC, TRD, and TRE between the pairs of the gate spacers 135 in the regions 100A to 100E, respectively. Afterwards, the sacrificial layers 104A to 104E are removed through the respective gate trenches TRA to TRE, such that the semiconductor layers 102A to 102E are suspended over the substrate 100. In some embodiments, the dummy gate structures 120A to 120E and the sacrificial layers 104A to 104E can be removed using suitable etching process, such as dry etch, wet etch, or combination thereof.

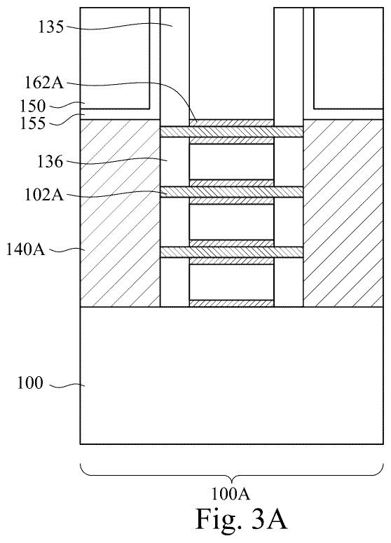

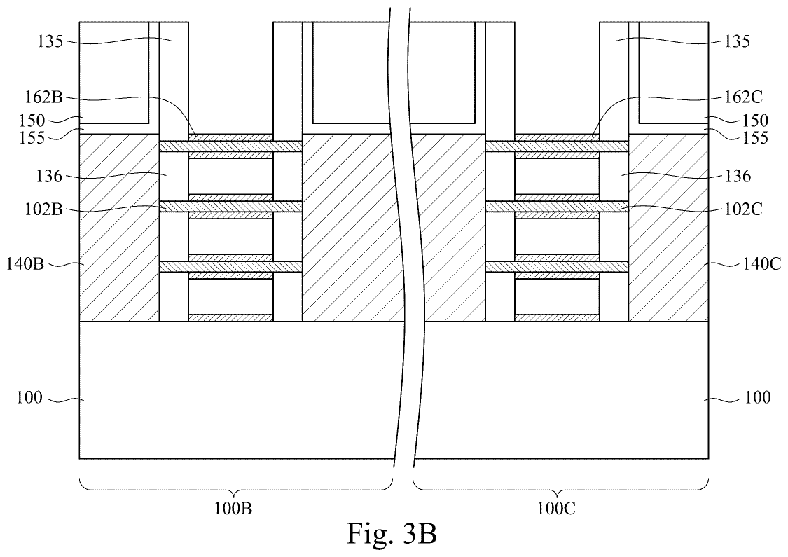

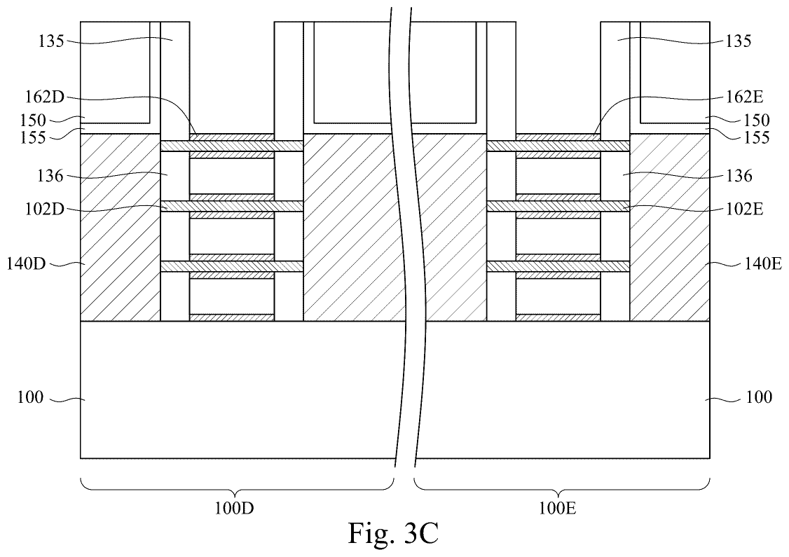

Reference is made to FIGS. 3A, 3B, and 3C. Interfacial layers 162A, 162B, 162C, 162D, and 162E are formed on the exposed surfaces of the semiconductor layers 102A to 102E, respectively. In some embodiments, the interfacial layers 162A to 162E may be made of a same material, such as silicon oxide (SiO₂), or the like, and may be formed using suitable process, such as a thermal oxidation process. In some embodiments, the interfacial layers 162A to 162E each may include a thickness in a range from about 0.2 nm to about 1.5, such as 1 nm.

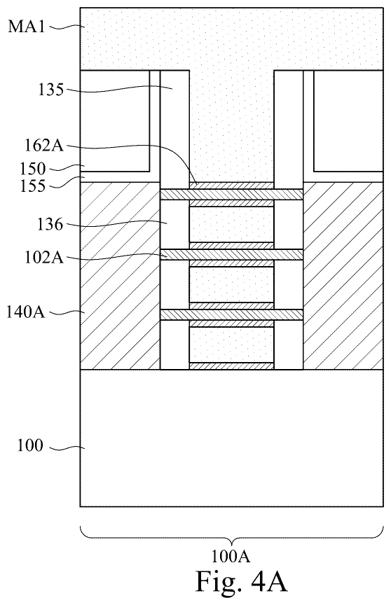

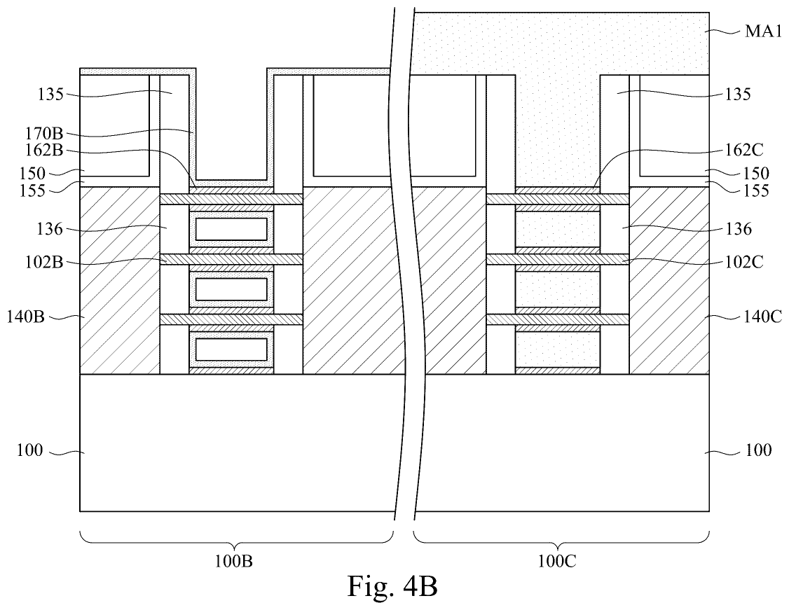

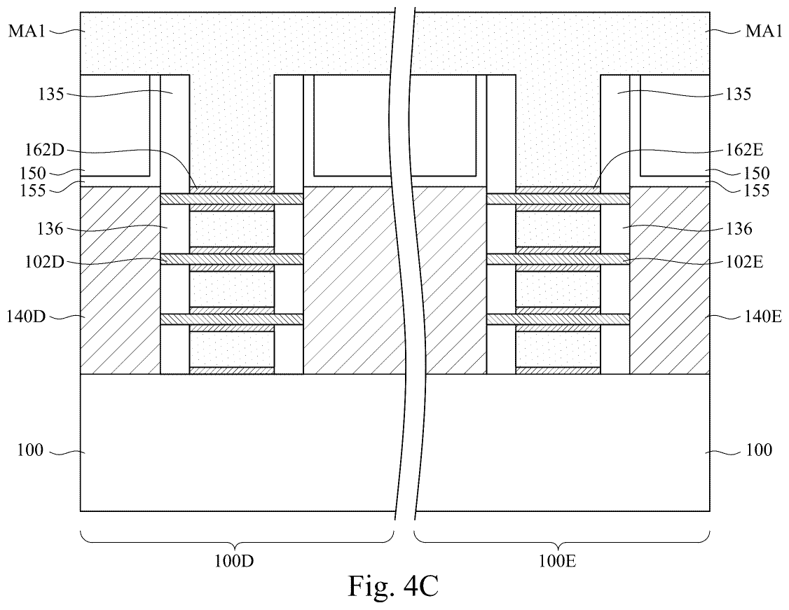

Reference is made to FIGS. 4A, 4B, and 4C. A patterned mask MA1 is formed over the substrate 100. In greater detail, the patterned mask MA1 is formed over the regions 100A, 100C, 100D, and 100E of the substrate 100, while leaving the region 100B of the substrate 100 exposed. Afterwards, a dipole layer 170B is formed over the exposed region 100B of the substrate 100, and in contact with the interfacial layer 162B within the exposed region 100B of the substrate 100. On the other hand, because the interfacial layers 162A, 162C, 162D, and 162E are covered by the patterned mask MA1, the dipole layer 170B is not formed on the surfaces of the interfacial layers 162A, 162C, 162D, and 162E.

In some embodiments, the dipole layer 170B may include a first dipole material, such as indium oxide (InO). The dipole layer 170B may be formed using suitable deposition process, such as chemical vapor deposition (CVD), atomic layer deposition (ALD), or the like. In some embodiments, the dipole layer 170B has a thickness in a range from about 2 nm to about 3.5 nm, such as 3 nm. In some embodiments, the dipole layer 170B is thicker than the interfacial layer 162B.

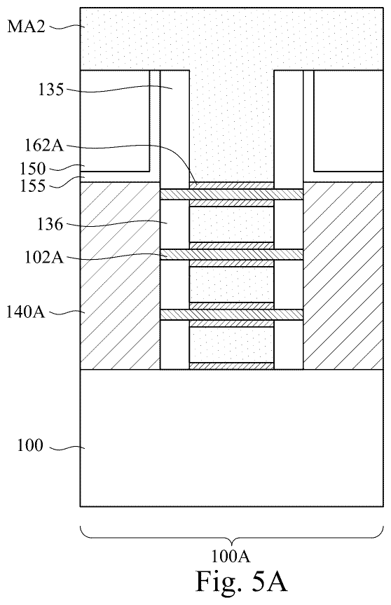

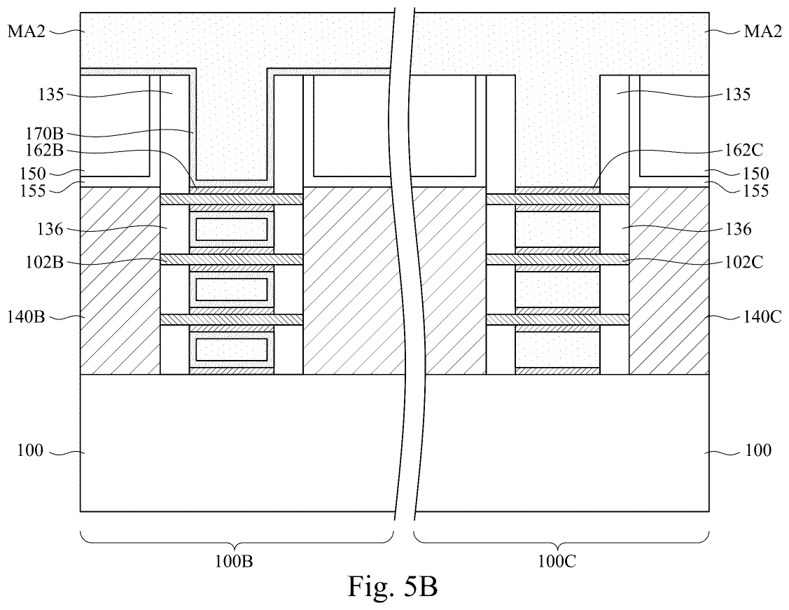

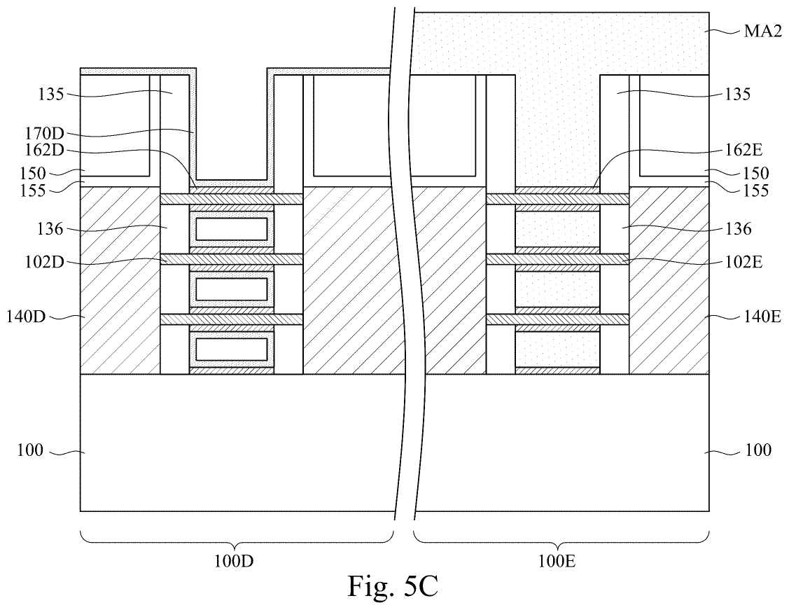

Reference is made to FIGS. 5A, 5B, and 5C. After the dipole layer 170B is formed, the patterned mask MA1 is removed. Then, a patterned mask MA2 is formed over the substrate 100. In greater detail, the patterned mask MA2 is formed over the regions 100A, 100B, 100C, and 100E of the substrate 100, while leaving the region 100D of the substrate 100 exposed. Afterwards, a dipole layer 170D is formed over the exposed region 100D of the substrate 100, and in contact with the interfacial layer 162D within the exposed region 100D of the substrate 100. On the other hand, because the interfacial layers 162A, 162B, 162C, and 162E are covered by the patterned mask MA2, the dipole layer 170D is not formed on the surfaces of the interfacial layers 162A, 162B, 162C, and 162E.

In some embodiments, the dipole layer 170D may include a second dipole material, such as aluminum oxide (AlO). The dipole layer 170D may be formed using suitable deposition process, such as chemical vapor deposition (CVD), atomic layer deposition (ALD), or the like. In some embodiments, the dipole layer 170D has a thickness in a range from about 2 nm to about 3.5 nm, such as 3 nm. In some embodiments, the dipole layer 170D is thicker than the interfacial layer 162D.

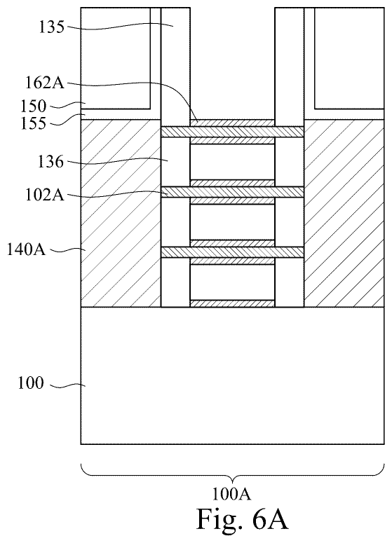

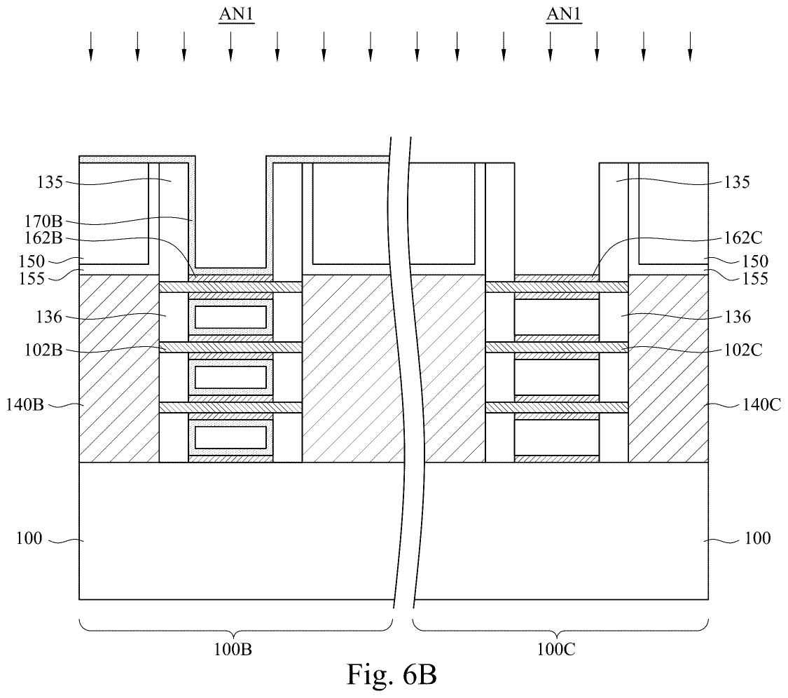

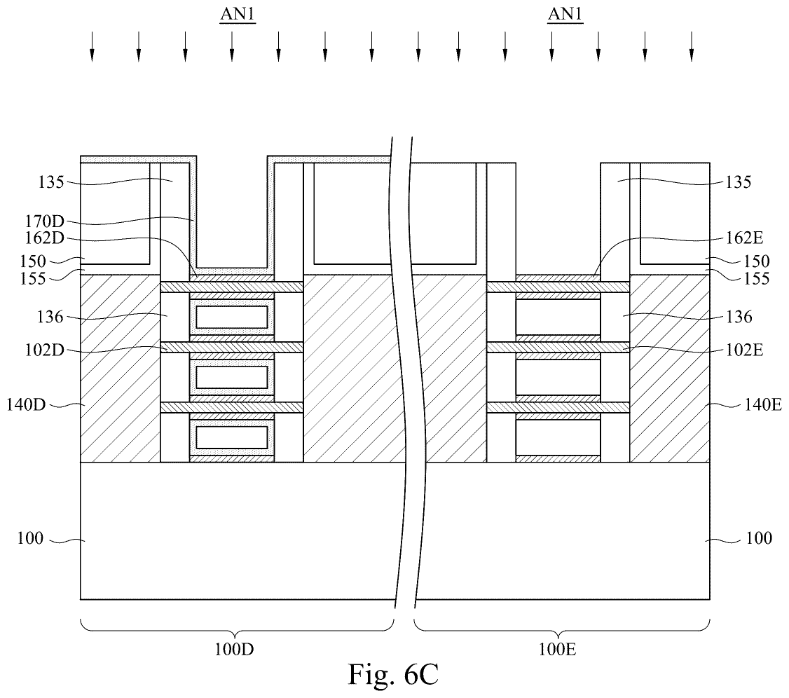

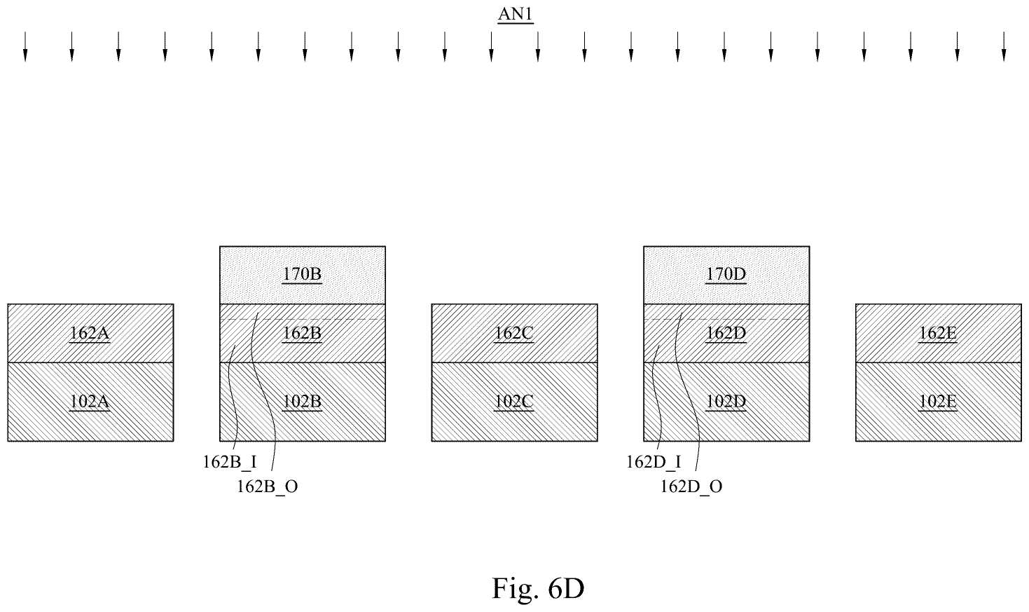

Reference is made to FIGS. 6A, 6B, 6C, and 6D. After the dipole layer 170D is formed, the patterned mask MA2 is removed. Then, an annealing process AN1 is performed, so as to drive the metal atoms of the dipole layers 170B and 170D into the interfacial layers 162B and 162D, respectively. In some embodiments, the annealing process AN1 is performed under a temperature in a range from about 300° C. to about 450° C.

FIG. 6D is a schematic view showing the result of the annealing process AN1 in different regions of the substrate 100. The annealing process AN1 is performed such that the metal atoms of the dipole layers 170B and 170D are diffused into outer regions of the interfacial layers 162B and 162D, respectively. As a result, after the annealing process AN1 is complete, the outer region 162B_O of the interfacial layer 162B has a higher concentration of first metal than the inner region 162B_I of the interfacial layer 162B. Similarly, the outer region 162D_O of the interfacial layer 162D has a higher concentration of second metal than the inner region 162D_I of the interfacial layer 162D. In some embodiments, the first metal is different from the second metal. For example, the first metal may include indium (In), and the second metal may include aluminum (Al). On the other hand, because no dipole layers are in contact with the interfacial layers 162A, 162C, and 162E, an entirety of the interfacial layers 162A, 162C, and 162E may be substantially free of the first and second metals. That is, an entirety of the interfacial layers 162A, 162C, and 162E may include substantially zero concentration of the first and second metals.

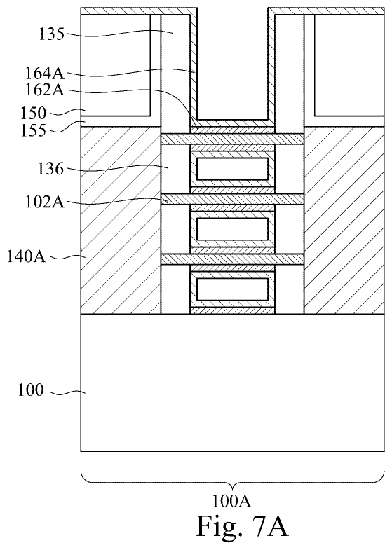

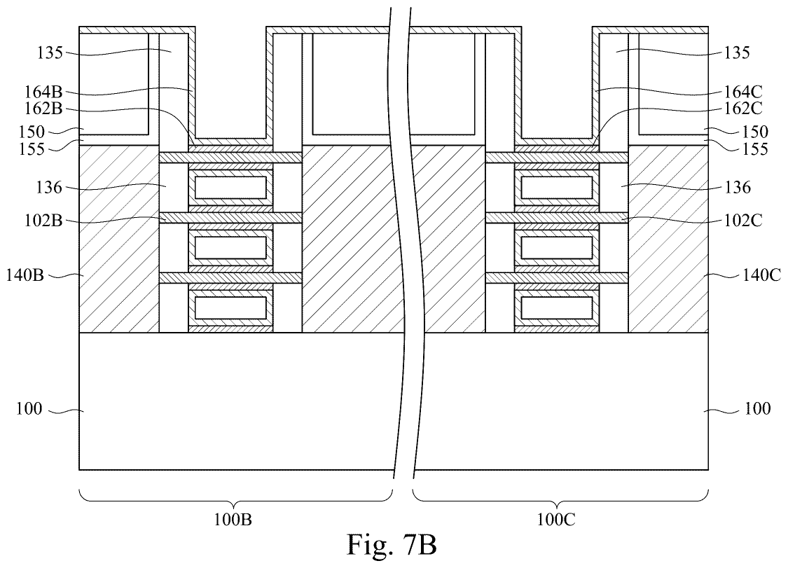

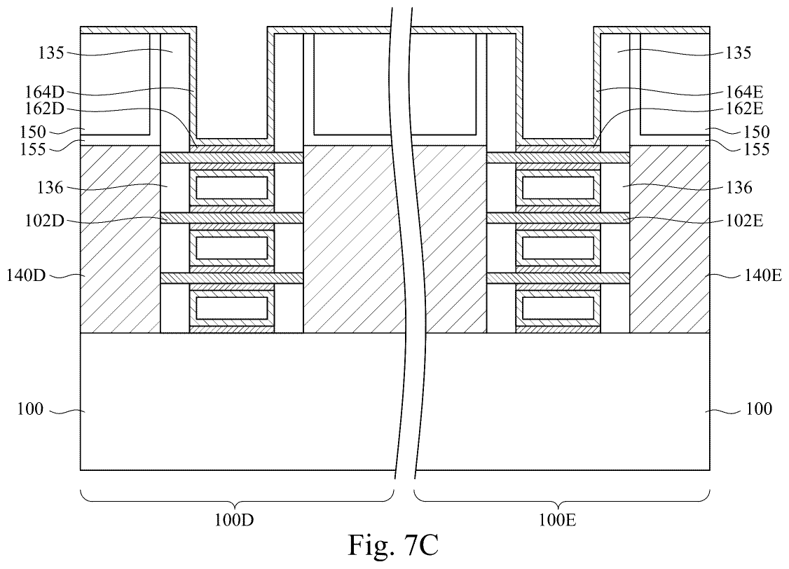

Reference is made to FIGS. 7A, 7B, and 7C. After the annealing process AN1 is complete, the dipole layers 170B and 170D are removed, so as to expose the interfacial layers 162B and 162D. The dipole layers 170B and 170D may be removed using suitable process, such as dry etch, wet etch, or combination thereof.

Then, high-k dielectric layers 164A, 164B, 164C, 164D, and 164E are formed on the exposed surfaces of the interfacial layers 162A to 162E, respectively. Examples of high-k dielectric material include HfO₂, HfSiO, HfSiON, HfTaO, HfTIO, HfZrO, zirconium oxide, aluminum oxide (Al₂O₃), titanium oxide, hafnium dioxide-alumina (HfO₂—Al₂O₃) alloy, other suitable high-k dielectric materials, and/or combinations thereof. In some embodiments, the high-k dielectric layers 164A to 164E may include hafnium oxide (HfO₂). The high-k dielectric layers 164A to 164E may be formed using suitable deposition process, such as chemical vapor deposition (CVD), atomic layer deposition (ALD), or the like. In some embodiments, the high-k dielectric layers 164A to 164E each may include a thickness in a range from about 2 nm to about 3.5 nm, such as 3 nm.

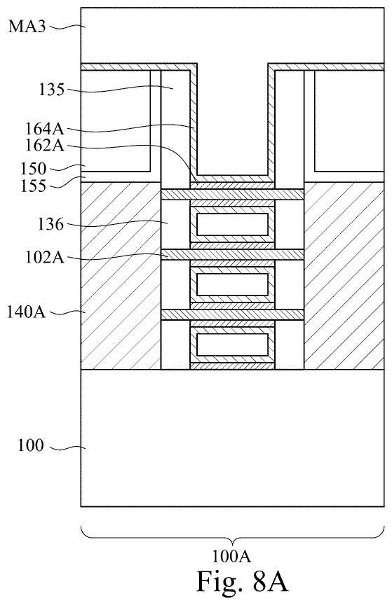

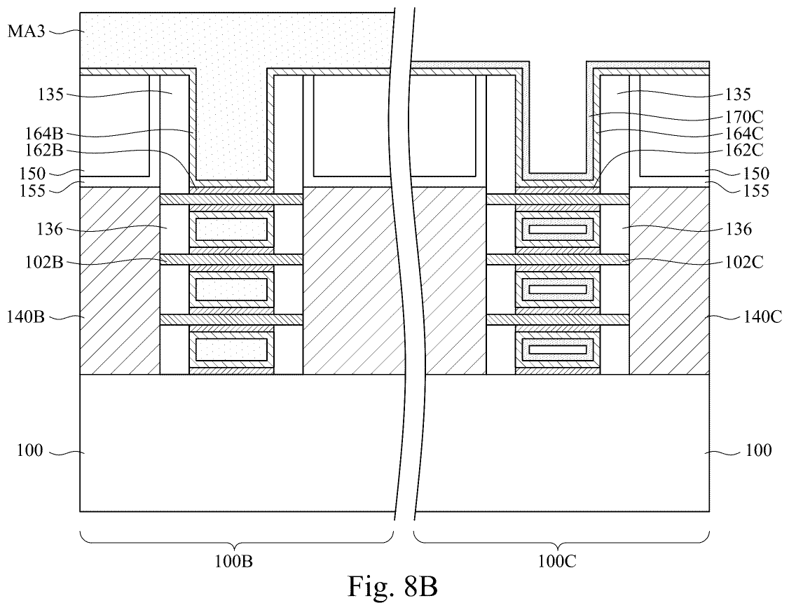

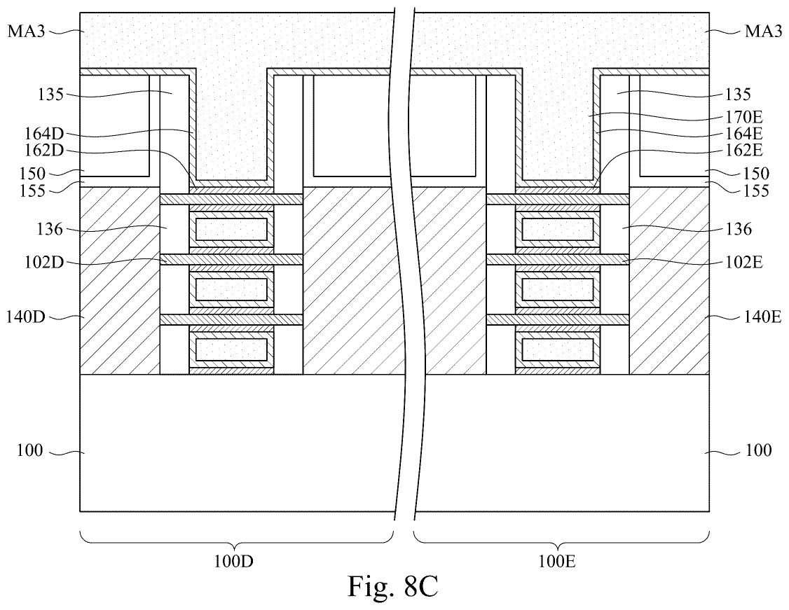

Reference is made to FIGS. 8A, 8B, and 8C. A patterned mask MA3 is formed over the substrate 100. In greater detail, the patterned mask MA3 is formed over the regions 100A, 100B, 100D, and 100E of the substrate 100, while leaving the region 100C of the substrate 100 exposed. Afterwards, a dipole layer 170C is formed over the exposed region 100C of the substrate 100, and in contact with the high-k dielectric layer 164C within the exposed region 100C of the substrate 100. On the other hand, because the high-k dielectric layers 164A, 164B, 164D, and 164E are covered by the patterned mask MA3, the dipole layer 170C is not formed on the surfaces of the high-k dielectric layers 164A, 164B, 164D, and 164E.

In some embodiments, the dipole layer 170C may include a first dipole material, such as indium oxide (InO). The dipole layer 170C may be formed using suitable deposition process, such as chemical vapor deposition (CVD), atomic layer deposition (ALD), or the like. In some embodiments, the dipole layer 170C has a thickness in a range from about 2 nm to about 3.5 nm, such as 3 nm. In some embodiments, the dipole layer 170C has substantially same thickness as the high-k dielectric layer 164C.

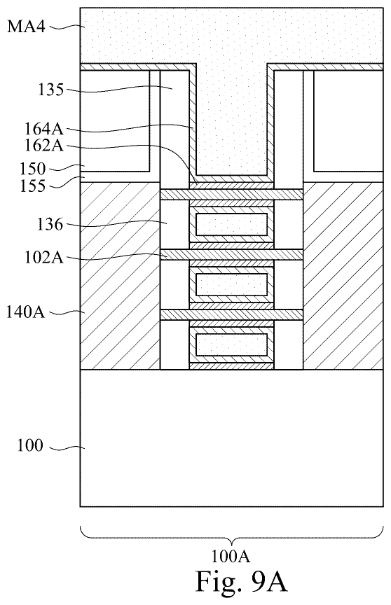

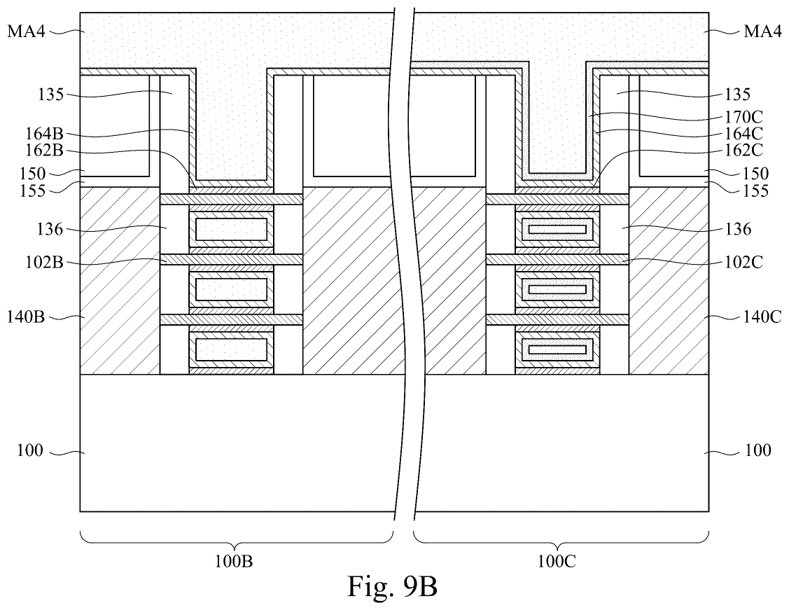

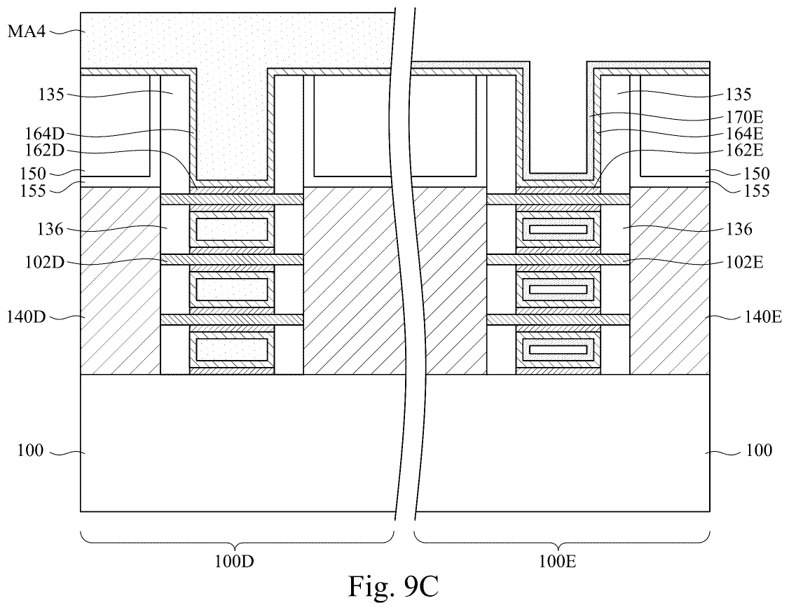

Reference is made to FIGS. 9A, 9B, and 9C. After the dipole layer 170C is formed, the patterned mask MA3 is removed. Then, a patterned mask MA4 is formed over the substrate 100. In greater detail, the patterned mask MA4 is formed over the regions 100A, 100B, 100C, and 100D of the substrate 100, while leaving the region 100E of the substrate 100 exposed. Afterwards, a dipole layer 170E is formed over the exposed region 100E of the substrate 100, and in contact with the high-k dielectric layer 164E within the exposed region 100E of the substrate 100. On the other hand, because the high-k dielectric layers 164A, 164B, 164C, and 164D are covered by the patterned mask MA4, the dipole layer 170E is not formed on the surfaces of the high-k dielectric layers 164A, 164B, 164C, and 164D.

In some embodiments, the dipole layer 170E may include a second dipole material, such as aluminum oxide (AlO). The dipole layer 170E may be formed using suitable deposition process, such as chemical vapor deposition (CVD), atomic layer deposition (ALD), or the like. In some embodiments, the dipole layer 170E has a thickness in a range from about 2 nm to about 3.5 nm, such as 3 nm. In some embodiments, the dipole layer 170E has substantially same thickness as the high-k dielectric layer 164E.

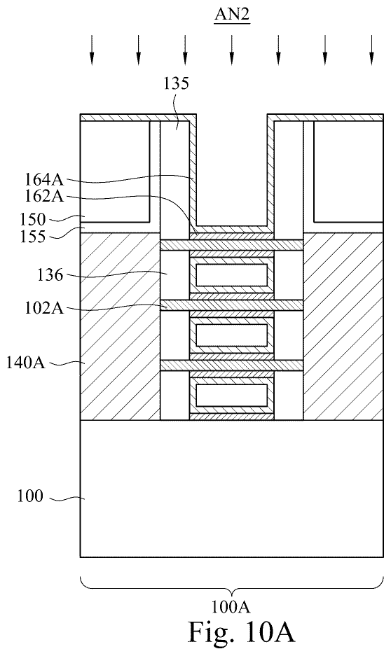

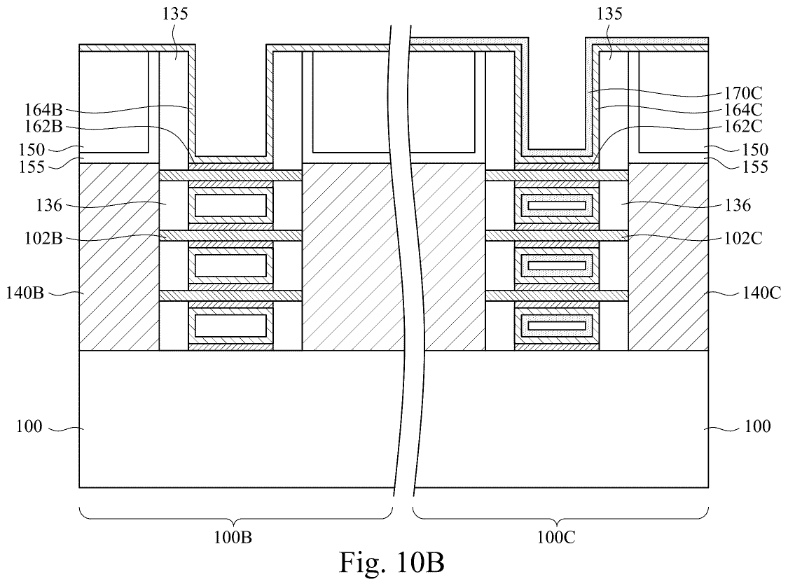

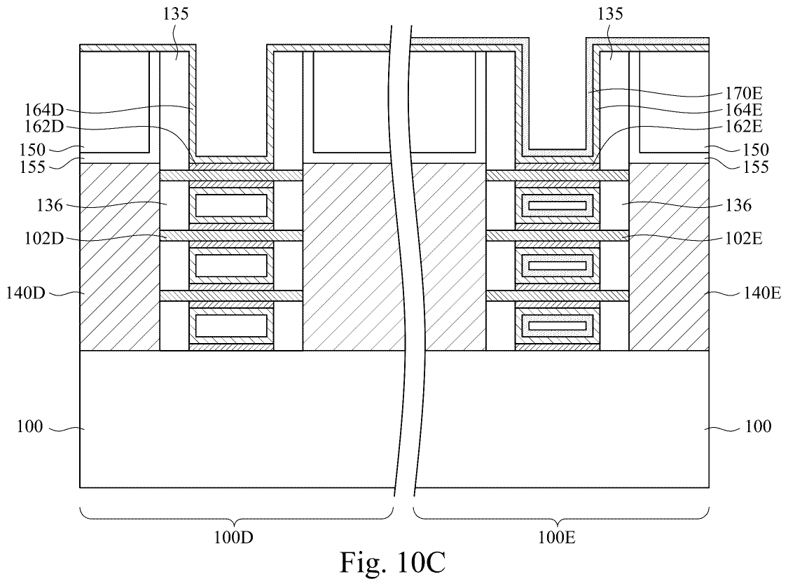

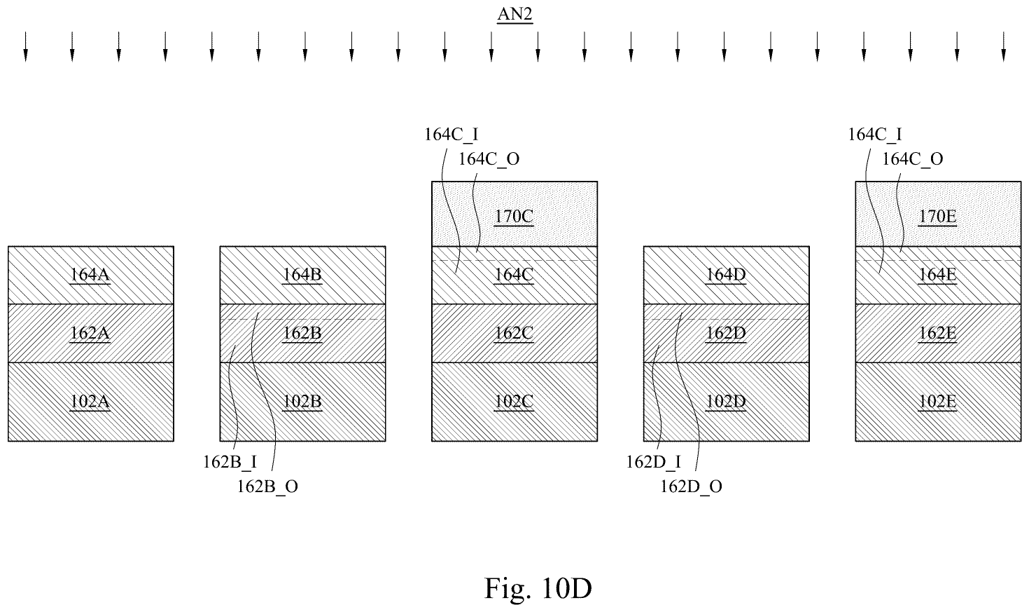

Reference is made to FIGS. 10A, 10B, 10C, and 10D. After the dipole layer 170E is formed, the patterned mask MA4 is removed. Then, an annealing process AN2 is performed, so as to drive the metal atoms of the dipole layers 170C and 170E into the high-k dielectric layers 164C and 164E, respectively. In some embodiments, the annealing process AN2 is performed under a temperature in a range from about 300° C. to about 450° C.

FIG. 10D is a schematic view showing the result of the annealing process AN2 in different regions of the substrate 100. The annealing process AN2 is performed such that the metal atoms of the dipole layers 170C and 170E are diffused into outer regions of the high-k dielectric layers 164C and 164E, respectively. As a result, after the annealing process AN2 is complete, the outer region 164C_O of the high-k dielectric layer 164C has a higher concentration of first metal than the inner region 164C_I of the high-k dielectric layer 164C. Similarly, the outer region 164E_O of the high-k dielectric layer 164E has a higher concentration of second metal than the inner region 164E_I of the high-k dielectric layer 164E. In some embodiments, the first metal is different from the second metal. For example, the first metal may include indium (In), and the second metal may include aluminum (Al). On the other hand, because no dipole layers are in contact with the high-k dielectric layers 164A, 164B, and 164D, an entirety of the high-k dielectric layers 164A, 164B, and 164D may be substantially free of the first and second metals. That is, an entirety of the high-k dielectric layers 164A, 164B, and 164D may include substantially zero concentration of the first and second metals.

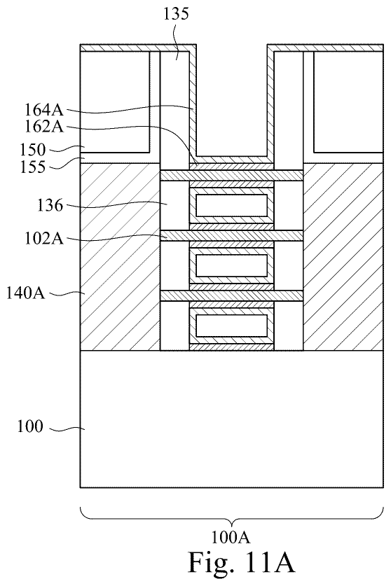

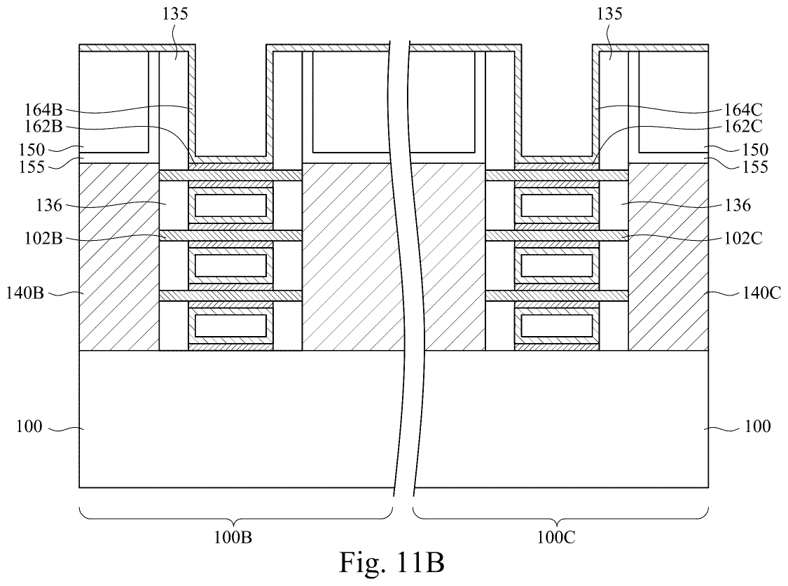

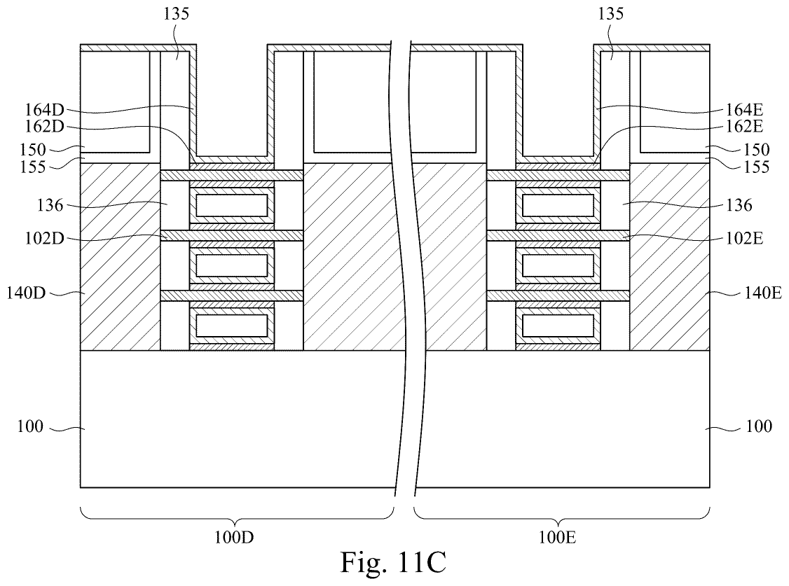

Reference is made to FIGS. 11A, 11B, and 11C. After the annealing process AN2 is complete, the dipole layers 170C and 170E are removed, so as to expose the high-k dielectric layers 164C and 164D. The dipole layers 170C and 170E a may be removed using suitable process, such as dry etch, wet etch, or combination thereof.

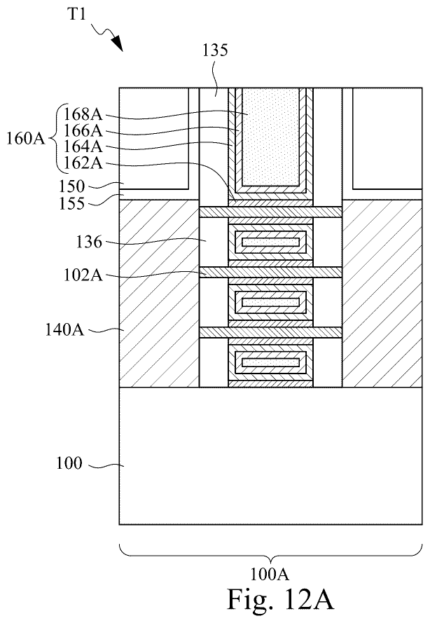

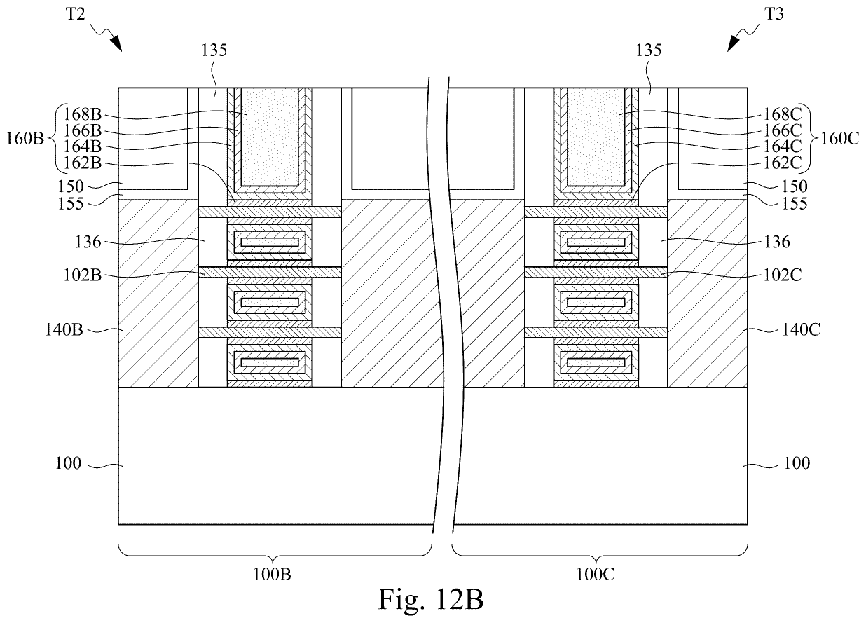

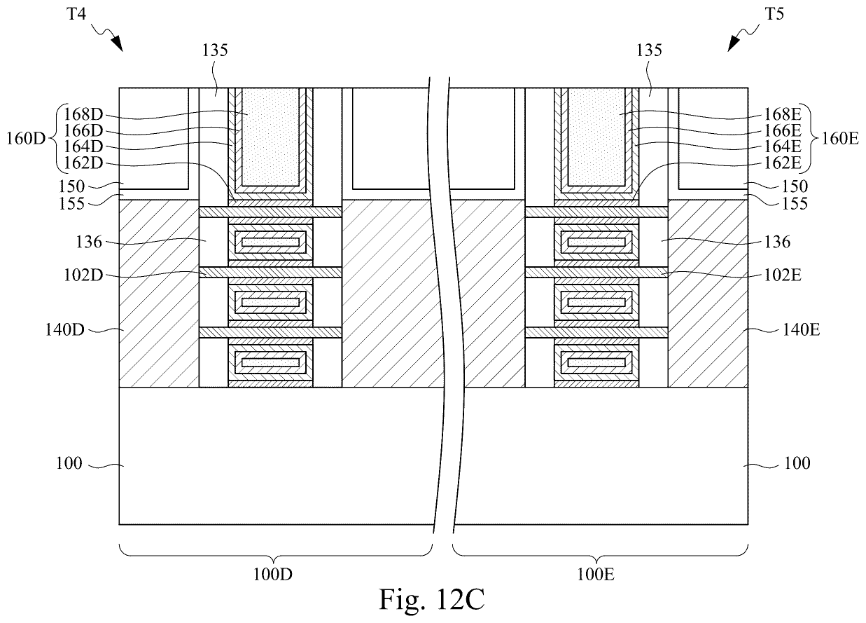

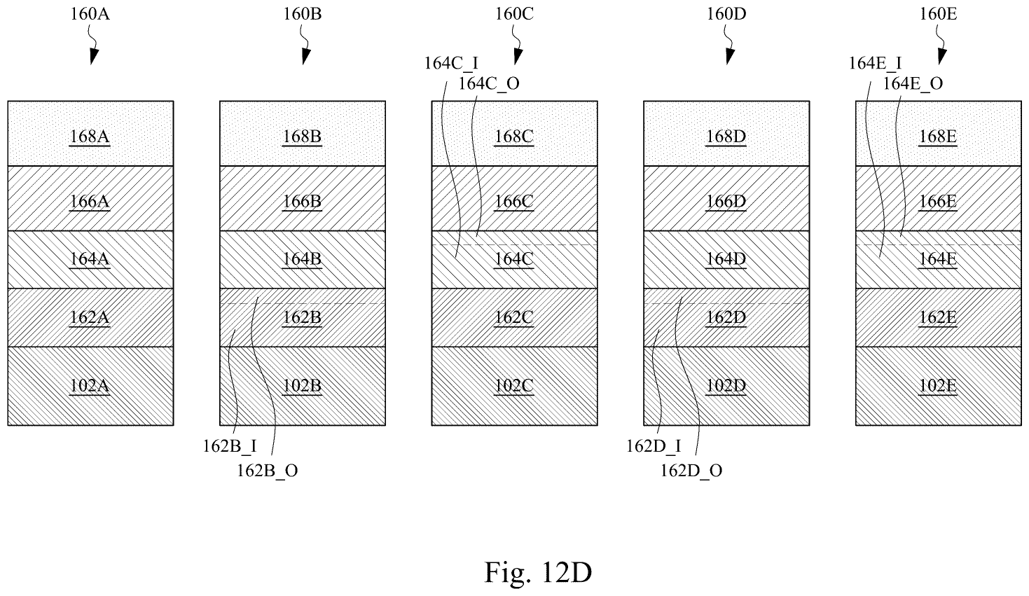

Reference is made to FIGS. 12A, 12B, 12C, and 12D. Work function metal layers 166A, 166B, 166C, 166D, and 166E are formed over the high-k dielectric layers 164A to 164E, respectively. Filling metals 168A, 168B, 168C, 168D, and 168E are formed over the work function metal layers 166A to 166E, respectively. Then, a planarization process, such as CMP, is performed to remove excess materials of the work function metal layers 166A to 166E and the filling metals 168A to 168E until the ILD layer 150 is exposed.

In some embodiments, the work function metal layers 166A to 166E may include titanium-based material or tantalum-based material, such as Ti, TiN, Ta, TaN, or the like. In some embodiments, the work function metal layers 166A to 166E may be made of a same material, such as titanium nitride (TiN). In some embodiments, the work function metal layers 166A to 166E each may include a thickness in a range from about 20 nm to about 24 nm, such as 22 nm. In some embodiments, the filling metals 168A to 168E may include metal, such as tungsten (W), aluminum (Al), copper (Cu), silver (Ag), or the like. In some embodiments, the filling metals 168A to 168E may be made of a same material, such as tungsten (W). In some embodiments, the filling metals 168A to 168E each may include a thickness in a range from about 18 nm to about 22 nm, such as 20 nm.

After the planarization process, metal gate structures 160A, 160B, 160C, 160D, and 160E are formed over the regions 100A to 100E of the substrate 100, respectively. The metal gate structure 160A may include the interfacial layer 162A, the high-k dielectric layer 164A, the work functional metal layer 166A, and the filling metal 168A. The metal gate structure 160B may include the interfacial layer 162B, the high-k dielectric layer 164B, the work functional metal layer 166B, and the filling metal 168B. The metal gate structure 160C may include the interfacial layer 162C, the high-k dielectric layer 164C, the work functional metal layer 166C, and the filling metal 168C. The metal gate structure 160D may include the interfacial layer 162D, the high-k dielectric layer 164D, the work functional metal layer 166D, and the filling metal 168D. The metal gate structure 160E may include the interfacial layer 162E, the high-k dielectric layer 164E, the work functional metal layer 166E, and the filling metal 168E.

In some embodiments, the metal gate structure 160A, the semiconductor layers 102A, and the source/drain epitaxial structures 140A may collectively serve as a transistor T1. The metal gate structure 160B, the semiconductor layers 102B, and the source/drain epitaxial structures 140B may collectively serve as a transistor T2. The metal gate structure 160C, the semiconductor layers 102C, and the source/drain epitaxial structures 140C may collectively serve as a transistor T3. The metal gate structure 160D, the semiconductor layers 102D, and the source/drain epitaxial structures 140D may collectively serve as a transistor T4. The metal gate structure 160E, the semiconductor layers 102E, and the source/drain epitaxial structures 140E may collectively serve as a transistor T5. In some embodiments, the transistor T1 may be a P-type transistor or an N-type transistor. The transistors T2 and T3 may be N-type transistors. The transistors T4 and T5 may be P-type transistors.

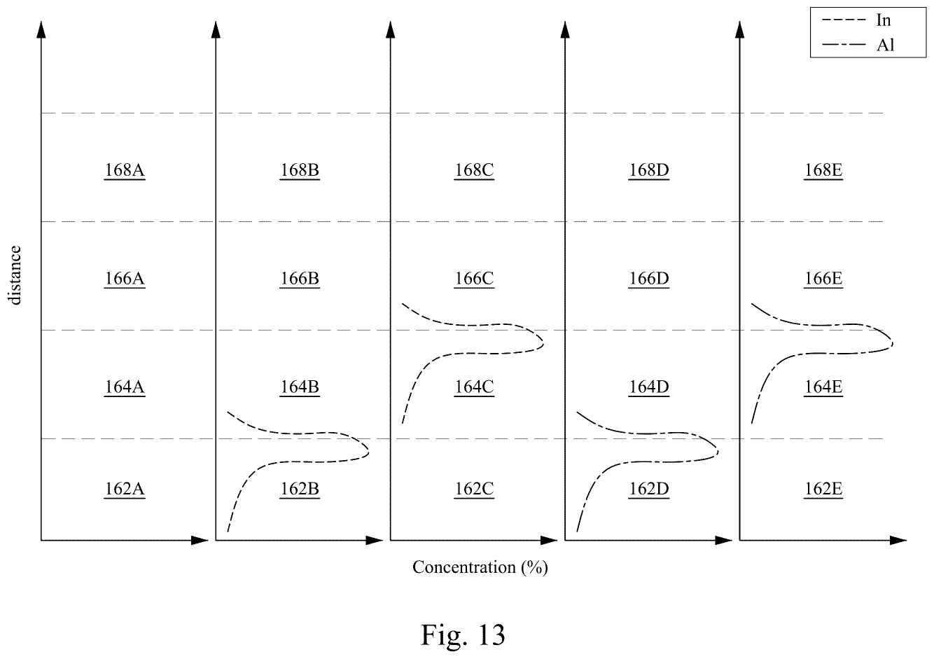

FIG. 12D is a schematic view showing the metal gate structures 160A to 160E. FIG. 13 illustrates the distributions of the first metal and the second metal in the metal gate structures 160A to 160E. With respect to the metal gate structures 160B and 160C, the outer region 162B_O of the interfacial layer 162B of the metal gate structure 160B and the outer region 164C_O of the high-k dielectric layer 164C of the metal gate structure 160C both include higher concentration of first metal. With respect to the metal gate structures 160D and 160E, the outer region 162D_O of the interfacial layer 162D of the metal gate structure 160D and the outer region 164E_O of the high-k dielectric layer 164E of the metal gate structure 160E both include higher concentration of second metal. In some embodiments, the metal gate structures 160B and 160C may be free of the second metal, and the metal gate structures 160D and 16EC may be free of the first metal. The metal gate structure 160A may be free of both the first and second metals.

The first and second metals may be used to tune the threshold voltage of the devices, and the first and second metals at different positions (e.g., in the interfacial layer or the high-k dielectric layer) may also affect the threshold voltages of the device. Accordingly, by driving the first and second metals into different layers of the corresponding metal gate structures, it is possible to create different threshold voltage levels in different devices over the substrate. For example, the transistors T1, T2, T3, T4, and T5 may include threshold voltages VT1, VT2, VT3, VT4, and VT5, in which VT2<VT3<VT1<VT5<VT4. Moreover, because the first and second metals are driven into the different layers of the corresponding metal gate structures without occupying additional spaces, the following formed work function metal layers and the filling metals can be easily filled into the gate trench without void. Additionally, the work function metal layers and the filling metals of different devices may be the same, which will reduce the process complexity.

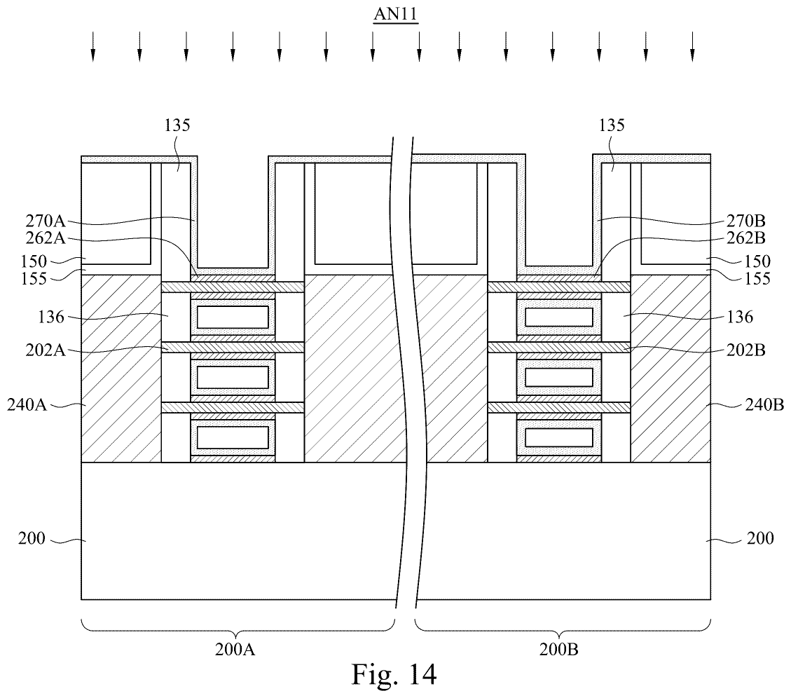

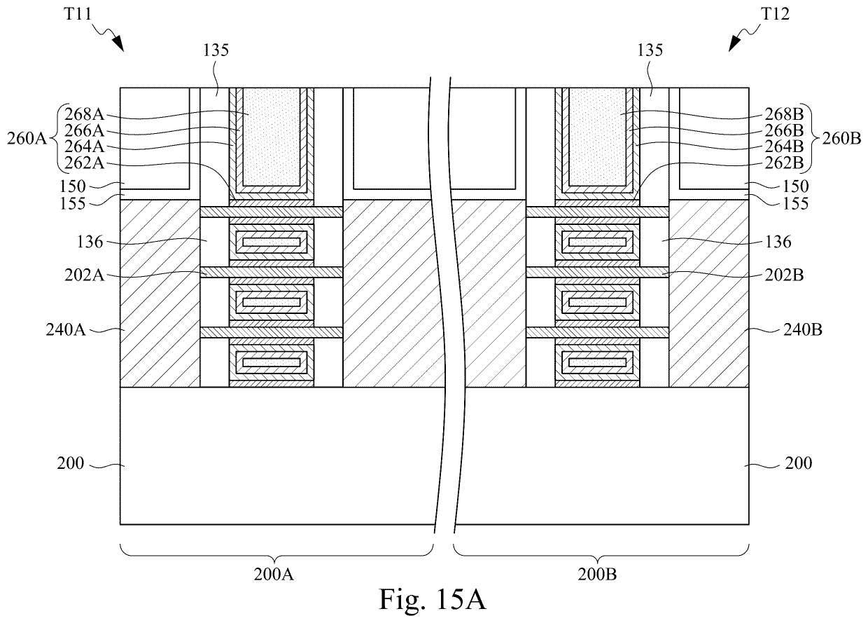

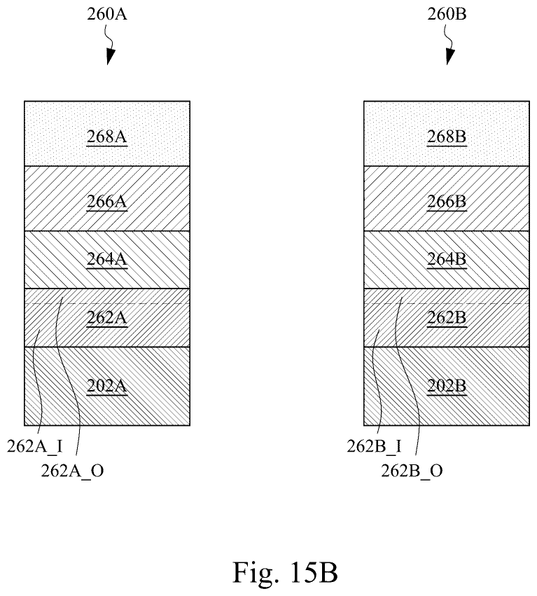

FIGS. 14 to 15B show cross-sectional views of intermediate structures at respective stages during an example method for forming a semiconductor device in accordance with some embodiments. It is noted that some elements of FIGS. 14 to 15B and the formation method thereof may be similar to those described with respect to FIGS. 1A to 12D, and thus relevant details will not be repeated for brevity.

Reference is made to FIG. 14. Shown there is a substrate 200, which includes regions 200A and 200B. FIG. 14 is similar to FIGS. 2A to 2C where dummy gate structures and sacrificial layers are removed. As a result, semiconductor layers 202A are suspended over the substrate 200, and semiconductor layers 202B are suspended over the substrate 200. In some embodiments, source/drain epitaxial structures 240A are disposed on opposite ends of each of the semiconductor layers 202A and source/drain epitaxial structures 240B are disposed on opposite ends of each of the semiconductor layers 202B. In some embodiments, the source/drain epitaxial structures 240A and 240B may be both N-type epitaxial structures or may be both P-type epitaxial structures.

Interfacial layers 262A and 262B are formed on the exposed surfaces of the semiconductor layers 202A and 202B, respectively. Afterwards, dipole layers 270A and 270B are formed over the interfacial layers 262A and 262B, respectively. The dipole layers 270A and 270B may include a same dipole material but different thicknesses. For example, the dipole layer 270B may be thicker than the dipole layer 270A. In some embodiments, when the source/drain epitaxial structures 240A and 240B are both N-type epitaxial structures, the dipole material of the dipole layers 270A and 270B may be indium oxide (InO). On the other hand, when the source/drain epitaxial structures 240A and 240B are both P-type epitaxial structures, the dipole material of the dipole layers 270A and 270B may be aluminum oxide (AlO). The dipole layers 270A and 270B may be formed at different time points. For example, a mask (not shown) may be formed covering the region 200B of the substrate 100, and the dipole layer 270A is deposited over the interfacial layer 262A. Then, the mask is removed, and another mask (not shown) may be formed covering the region 200A of the substrate 100, and the dipole layer 270B is deposited over the interfacial layer 262B.

After the dipole layers 270A and 270B are formed, an annealing process AN11 may be performed to drive the metal atoms of the dipole layers 270A and 270B into the interfacial layers 262A and 262B, respectively. Because the dipole layer 270B is thicker than the dipole layer 270A, the interfacial layer 262B may include a higher concentration of metal atoms than the interfacial layer 262A as a result of the annealing process.

Reference is made to FIGS. 15A and 15B. After the annealing process AN11 is complete, the dipole layers 270A and 270B are removed. Then, high-k dielectric layers 264A and 264B are formed over the interfacial layers 262A and 262B, respectively. Work function metal layers 266A and 266B are formed over the high-k dielectric layers 264A and 264B, respectively. Filling metals 268A and 268B are formed over the work function metal layers 266A and 266B, respectively. As a result, metal gate structures 260A and 260B are formed. The metal gate structure 260A, the semiconductor layer 202A, and the source/drain epitaxial structures 240A may collective serve as a transistor T11, and metal gate structure 260B, the semiconductor layer 202B, and the source/drain epitaxial structures 240B may collective serve as a transistor T12.

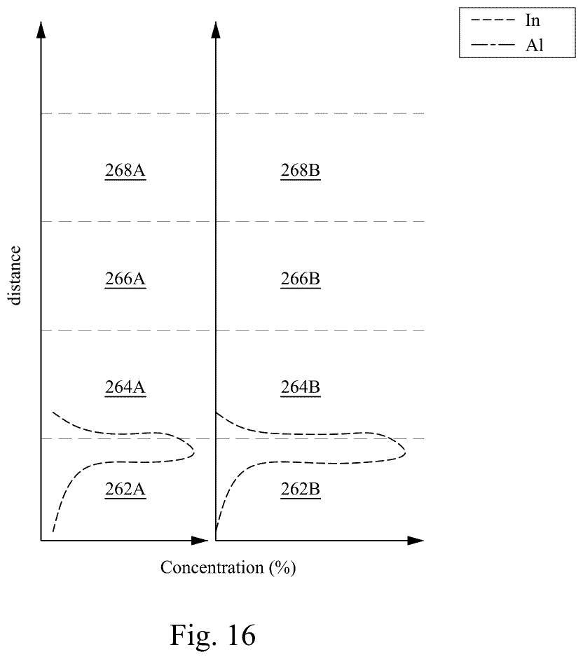

FIG. 15B is a schematic view showing the metal gate structures 260A and 260B. FIG. 16 illustrates the distributions of the metal atoms in the metal gate structures 260A and 260B. With respect to the metal gate structure 260A, the outer region 262A_O of the interfacial layer 262A of the metal gate structure 260A includes a higher concentration of metal atoms than the inner region 262A_I of the interfacial layer 262A of the metal gate structure 260A. With respect to the metal gate structure 260B, the outer region 262B_O of the interfacial layer 262B of the metal gate structure 260B includes a higher concentration of metal atoms than the inner region 262B_I of the interfacial layer 262B of the metal gate structure 260B. However, due to the thicker dipole layer 270B as discussed above, the outer region 262B_O of the interfacial layer 262B may include a higher metal concentration than the outer region 262A_O of the interfacial layer 262A.

As mentioned above, the metal atoms of the dipole layers may be used to tune the threshold voltage of the devices. Accordingly, by driving different amounts of metal atoms into different layers of the corresponding metal gate structures, it is possible to create different threshold voltage levels in different devices over the substrate.

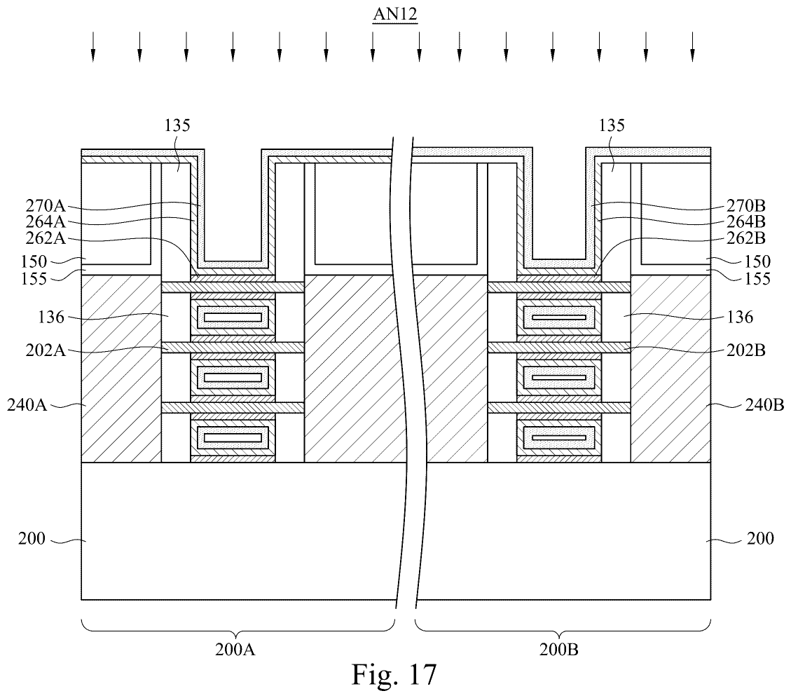

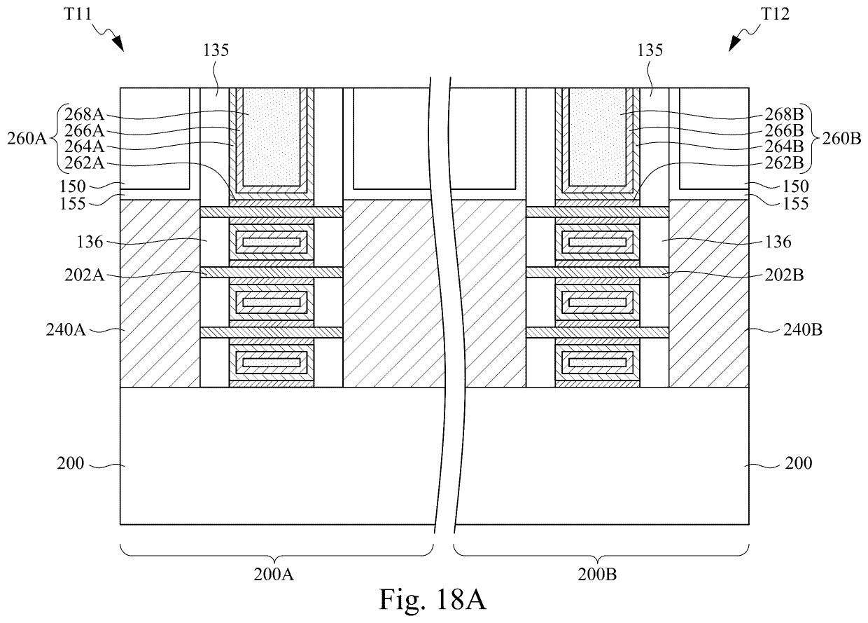

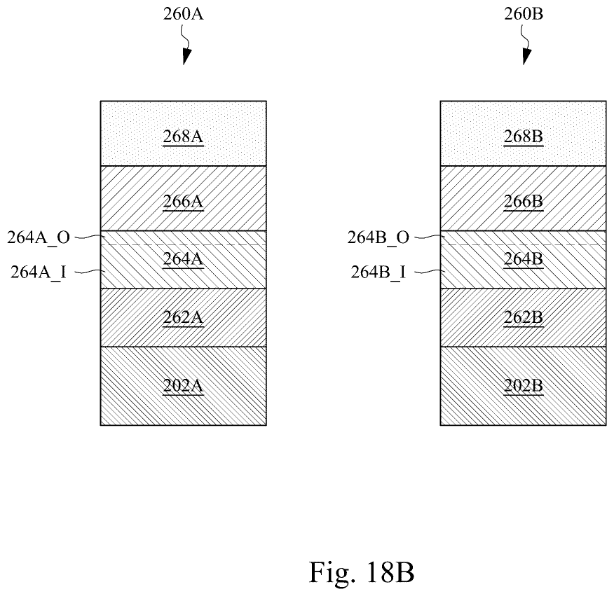

FIGS. 17 to 18B show cross-sectional views of intermediate structures at respective stages during an example method for forming a semiconductor device in accordance with some embodiments. It is noted that some elements of FIGS. 17 to 18B and the formation method thereof may be similar to those described with respect to FIGS. 1A to 12D and 14 to 15B, and thus relevant details will not be repeated for brevity.

Reference is made to FIG. 17. Shown there is a substrate 200, which includes regions 200A and 200B. FIG. 17 is similar to FIGS. 2A to 2C where dummy gate structures and sacrificial layers are removed. As a result, semiconductor layers 202A are suspended over the substrate 200, and semiconductor layers 202B are suspended over the substrate 200. In some embodiments, source/drain epitaxial structures 240A are disposed on opposite ends of each of the semiconductor layers 202A and source/drain epitaxial structures 240B are disposed on opposite ends of each of the semiconductor layers 202B. In some embodiments, the source/drain epitaxial structures 240A and 240B may be both N-type epitaxial structures or may be both P-type epitaxial structures.

Interfacial layers 262A and 262B are formed on the exposed surfaces of the semiconductor layers 202A and 202B, respectively. Then, high-k dielectric layers 264A and 264B are formed over the interfacial layers 262A and 262B, respectively.

Afterwards, dipole layers 270A and 270B are formed over the high-k dielectric layers 264A and 264B, respectively. The dipole layers 270A and 270B may include a same dipole material but different thicknesses. For example, the dipole layer 270B may be thicker than the dipole layer 270A. In some embodiments, when the source/drain epitaxial structures 240A and 240B are both N-type epitaxial structures, the dipole material of the dipole layers 270A and 270B may be indium oxide (InO). On the other hand, when the source/drain epitaxial structures 240A and 240B are both P-type epitaxial structures, the dipole material of the dipole layers 270A and 270B may be aluminum oxide (AlO). The dipole layers 270A and 270B may be formed at different time points. For example, a mask (not shown) may be formed covering the region 200B of the substrate 100, and the dipole layer 270A is deposited over the high-k dielectric layer 264A. Then, the mask is removed, and another mask (not shown) may be formed covering the region 200A of the substrate 100, and the dipole layer 270B is deposited over the high-k dielectric layer 264B.

After the dipole layers 270A and 270B are formed, an annealing process AN12 may be performed to drive the metal atoms of the dipole layers 270A and 270B into the high-k dielectric layers 264A and 264B, respectively. Because the dipole layer 270B is thicker than the dipole layer 270A, the high-k dielectric layer 264B may include a higher concentration of metal atoms than the high-k dielectric layer 264A as a result of the annealing process.

Reference is made to FIGS. 18A and 18B. After the annealing process AN12 is complete, the dipole layers 270A and 270B are removed. Then, work function metal layers 266A and 266B are formed over the high-k dielectric layers 264A and 264B, respectively. Filling metals 268A and 268B are formed over the work function metal layers 266A and 266B, respectively. As a result, metal gate structures 260A and 260B are formed. The metal gate structure 260A, the semiconductor layer 202A, and the source/drain epitaxial structures 240A may collective serve as a transistor T11, and metal gate structure 260B, the semiconductor layer 202B, and the source/drain epitaxial structures 240B may collective serve as a transistor T12.

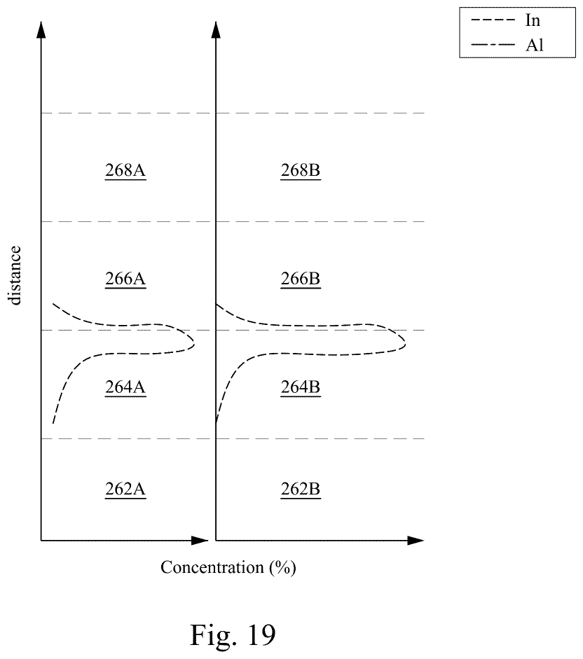

FIG. 18B is a schematic view showing the metal gate structures 260A and 260B. FIG. 19 illustrates the distributions of the metal atoms in the metal gate structures 260A and 260B. With respect to the metal gate structure 260A, the outer region 264A_O of the high-k dielectric layer 264A of the metal gate structure 260A includes a higher concentration of metal atoms than the inner region 264A_I of the high-k dielectric layer 264A of the metal gate structure 260A. With respect to the metal gate structure 260B, the outer region 264B_O of the high-k dielectric layer 264B of the metal gate structure 260B includes a higher concentration of metal atoms than the inner region 264B_I of the high-k dielectric layer 264B of the metal gate structure 260B. However, due to the thicker dipole layer 270B as discussed above, the outer region 264B_O of the high-k dielectric layer 264B may include a higher metal concentration than the outer region 264A_O of the high-k dielectric layer 264B.

As mentioned above, the metal atoms of the dipole layers may be used to tune the threshold voltage of the devices. Accordingly, by driving different amounts of metal atoms into different layers of the corresponding metal gate structures, it is possible to create different threshold voltage levels in different devices over the substrate.

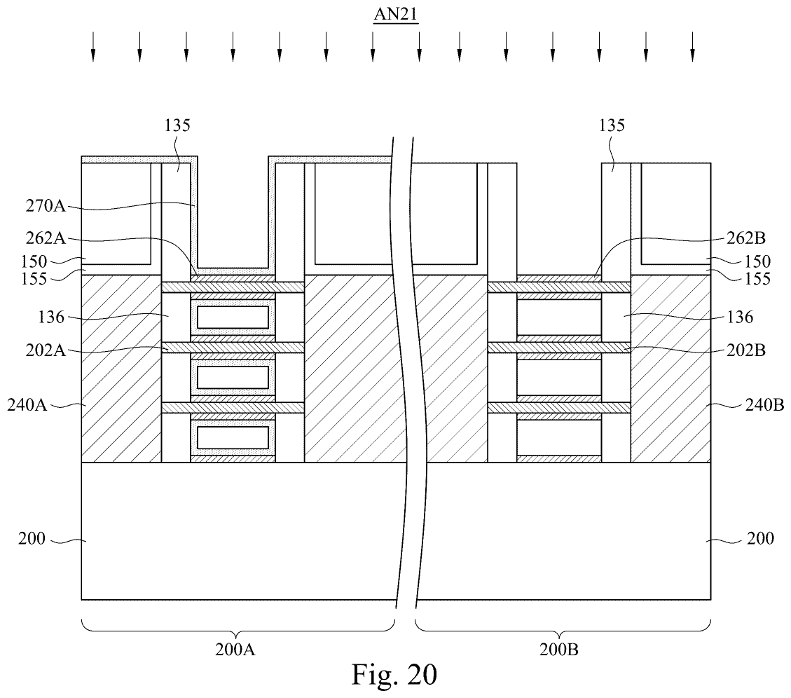

FIGS. 20 to 22B show cross-sectional views of intermediate structures at respective stages during an example method for forming a semiconductor device in accordance with some embodiments. It is noted that some elements of FIGS. 20 to 22B and the formation method thereof may be similar to those described above, and thus relevant details will not be repeated for brevity.

Reference is made to FIG. 20. FIG. 20 is similar to FIGS. 2A to 2C where dummy gate structures and sacrificial layers are removed. As a result, semiconductor layers 202A are suspended over the substrate 200, and semiconductor layers 202B are suspended over the substrate 200. In some embodiments, source/drain epitaxial structures 240A are disposed on opposite ends of each of the semiconductor layers 202A and source/drain epitaxial structures 240B are disposed on opposite ends of each of the semiconductor layers 202B. In some embodiments, the source/drain epitaxial structures 240A and 240B may be both N-type epitaxial structures or may be both P-type epitaxial structures.

Interfacial layers 262A and 262B are formed on the exposed surfaces of the semiconductor layers 202A and 202B, respectively. Afterwards, a dipole layer 270A is formed over the interfacial layer 262A. In some embodiments, the dipole layer 270A can be formed by, for example, forming a patterned mask (not shown) covering the region 200B of the substrate 200 and exposing the region 200A of the substrate 200, depositing the dipole layer 270A over the interfacial layer 262A, and then removing the patterned mask. As a result, once the dipole layer 270A is formed, the surface of the interfacial layer 262B is free of coverage by a dipole material.

In some embodiments, when the source/drain epitaxial structures 240A and 240B are both N-type epitaxial structures, the dipole material of the dipole layer 270A may be indium oxide (InO). On the other hand, when the source/drain epitaxial structures 240A and 240B are both P-type epitaxial structures, the dipole material of the dipole layer 270A may be aluminum oxide (AlO).

After the dipole layer 270A is formed, an annealing process AN21 may be performed to drive the metal atoms of the dipole layer 270A into the interfacial layer 262A. It is noted that, during the annealing process AN21, the surface of the interfacial layer 262B is free of coverage by a dipole material, and thus no metal atoms are driven into the interfacial layer 262B.

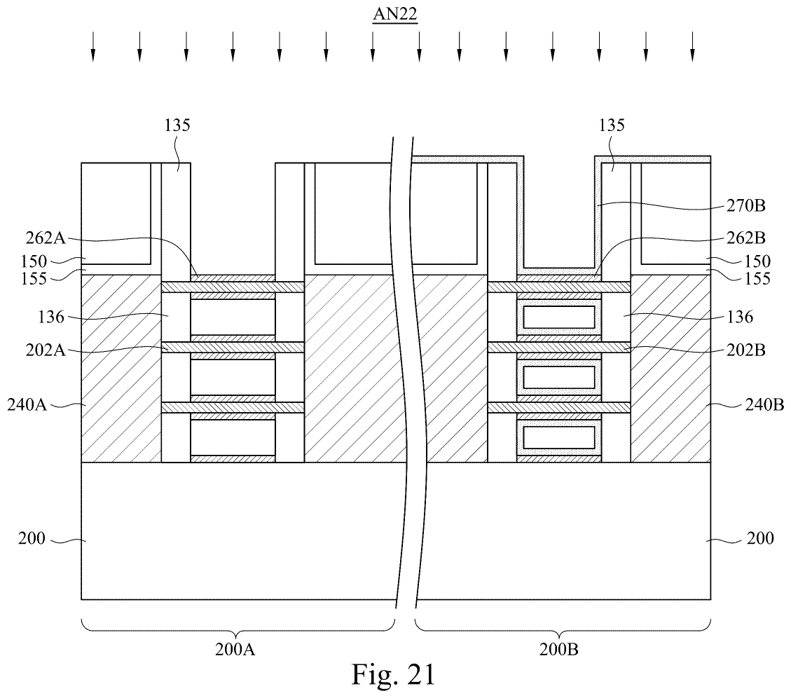

Reference is made to FIG. 21. After the annealing process AN21 is complete, the dipole layer 270A is removed. Then, a dipole layer 270B is formed over the interfacial layer 262B. In some embodiments, the dipole layer 270B can be formed by, for example, forming a patterned mask (not shown) covering the region 200A of the substrate 200 and exposing the region 200B of the substrate 200, depositing the dipole layer 270B over the interfacial layer 262B, and then removing the patterned mask. As a result, once the dipole layer 270B is formed, the surface of the interfacial layer 262A is free of coverage by a dipole material.

In some embodiments, the dipole layers 270A and 270B may include a same material. For example, when the source/drain epitaxial structures 240A and 240B are both N-type epitaxial structures, the dipole material of the dipole layer 270B may be indium oxide (InO). On the other hand, when the source/drain epitaxial structures 240A and 240B are both P-type epitaxial structures, the dipole material of the dipole layer 270B may be aluminum oxide (AlO). Moreover, the dipole layers 270A and 270B may include substantially a same thickness. That is, the deposition conditions of the dipole layers 270A and 270B may be substantially the same.

After the dipole layer 270B is formed, an annealing process AN22 may be performed to drive the metal atoms of the dipole layer 270B into the interfacial layer 262B. It is noted that, during the annealing process AN22, the surface of the interfacial layer 262A is free of coverage by a dipole material, and thus no metal atoms are driven into the interfacial layer 262A. The difference between the annealing process AN21 of FIG. 20 and the annealing process AN22 of FIG. 21 is that the duration of the annealing process AN22 is longer than the duration of the annealing process AN21. As a result, although the dipole layers 270A and 270B may include a same thickness and a same material, the annealing process AN22 with longer duration may drive more metal atoms into the interfacial layer 262B.

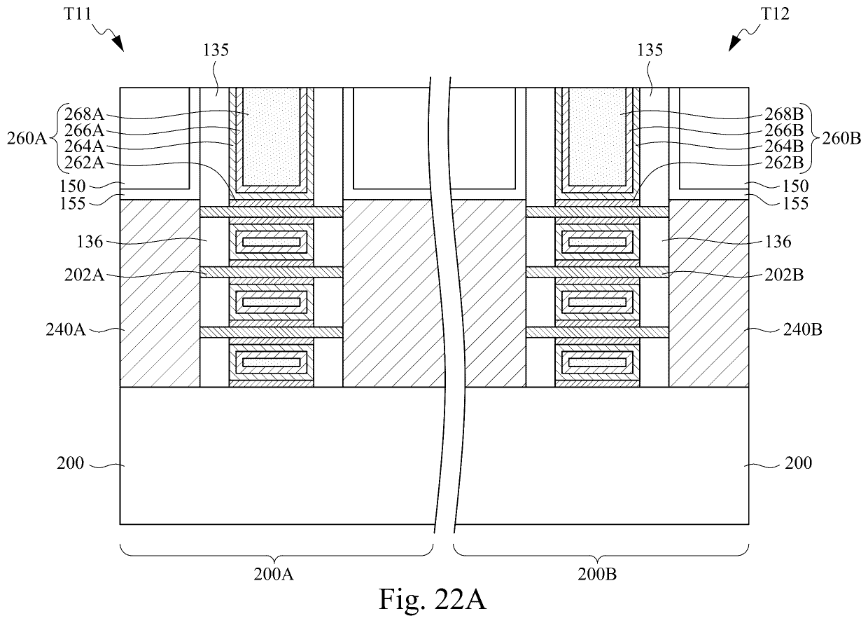

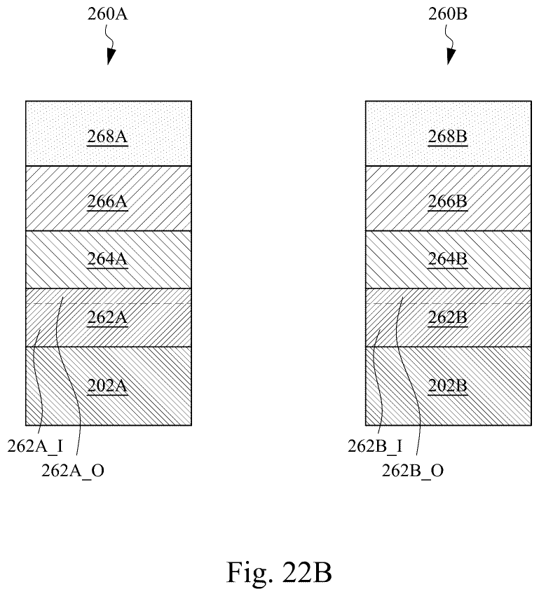

Reference is made to FIGS. 22A and 22B. After the annealing process AN22 is complete, the dipole layer 270B is removed. Then, high-k dielectric layers 264A and 264B are formed over the interfacial layers 262A and 262B, respectively. Work function metal layers 266A and 266B are formed over the high-k dielectric layers 264A and 264B, respectively. Filling metals 268A and 268B are formed over the work function metal layers 266A and 266B, respectively. As a result, metal gate structures 260A and 260B are formed. The metal gate structure 260A, the semiconductor layer 202A, and the source/drain epitaxial structures 240A may collective serve as a transistor T11, and metal gate structure 260B, the semiconductor layer 202B, and the source/drain epitaxial structures 240B may collective serve as a transistor T12.

FIG. 22B is a schematic view showing the metal gate structures 260A and 260B. With respect to the metal gate structure 260A, the outer region 262A_O of the interfacial layer 262A of the metal gate structure 260A includes a higher concentration of metal atoms than the inner region 262A_I of the interfacial layer 262A of the metal gate structure 260A. With respect to the metal gate structure 260B, the outer region 262B_O of the interfacial layer 262B of the metal gate structure 260B includes a higher concentration of metal atoms than the inner region 262B_I of the interfacial layer 262B of the metal gate structure 260B. However, due to the longer duration of the annelaning process AN22 as discussed above, the outer region 262B_O of the interfacial layer 262B may include a higher concentration of metal atoms than the outer region 262A_O of the interfacial layer 262A. It is noted that the metal atom distributions in the metal gate structures 260A and 260B may be similar to those illustrated in FIG. 16.

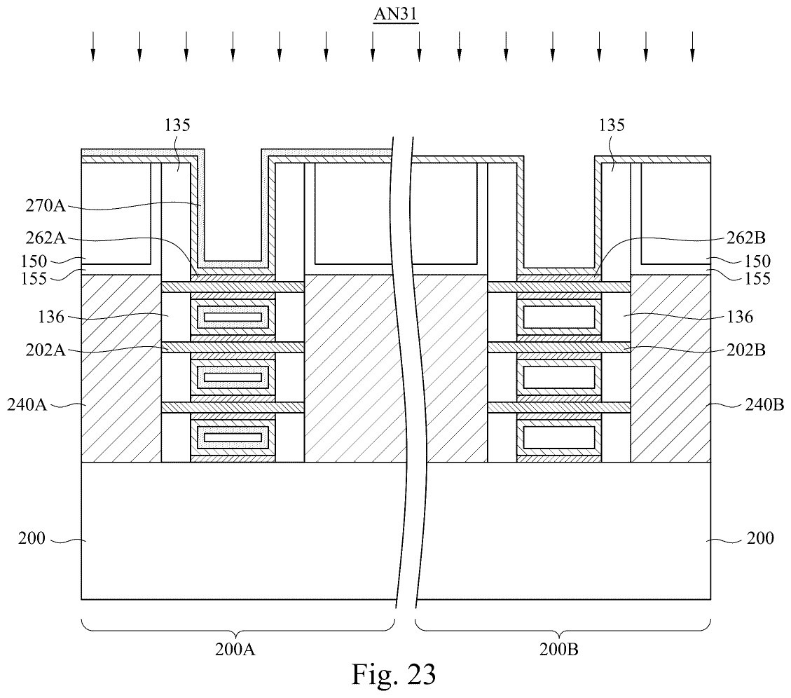

FIGS. 23 to 25B show cross-sectional views of intermediate structures at respective stages during an example method for forming a semiconductor device in accordance with some embodiments. It is noted that some elements of FIGS. 23 to 25B and the formation method thereof may be similar to those described above, and thus relevant details will not be repeated for brevity.

Reference is made to FIG. 23. FIG. 23 is similar to FIGS. 2A to 2C where dummy gate structures and sacrificial layers are removed. As a result, semiconductor layers 202A are suspended over the substrate 200, and semiconductor layers 202B are suspended over the substrate 200. In some embodiments, source/drain epitaxial structures 240A are disposed on opposite ends of each of the semiconductor layers 202A and source/drain epitaxial structures 240B are disposed on opposite ends of each of the semiconductor layers 202B. In some embodiments, the source/drain epitaxial structures 240A and 240B may be both N-type epitaxial structures or may be both P-type epitaxial structures.

Interfacial layers 262A and 262B are formed on the exposed surfaces of the semiconductor layers 202A and 202B, respectively. Then, high-k dielectric layers 264A and 264B are formed over the interfacial layers 262A and 262B, respectively.

Afterwards, a dipole layer 270A is formed over the high-k dielectric layer 264A. In some embodiments, the dipole layer 270A can be formed by, for example, forming a patterned mask (not shown) covering the region 200B of the substrate 200 and exposing the region 200A of the substrate 200, depositing the dipole layer 270A over the high-k dielectric layer 264A, and then removing the patterned mask. As a result, once the dipole layer 270A is formed, the surface of the high-k dielectric layer 264B is free of coverage by a dipole material.

In some embodiments, when the source/drain epitaxial structures 240A and 240B are both N-type epitaxial structures, the dipole material of the dipole layer 270A may be indium oxide (InO). On the other hand, when the source/drain epitaxial structures 240A and 240B are both P-type epitaxial structures, the dipole material of the dipole layer 270A may be aluminum oxide (AlO).

After the dipole layer 270A is formed, an annealing process AN31 may be performed to drive the metal atoms of the dipole layer 270A into the high-k dielectric layer 264A. It is noted that, during the annealing process AN31, the surface of the high-k dielectric layer 264B is free of coverage by a dipole material, and thus no metal atoms are driven into the high-k dielectric layer 264B.

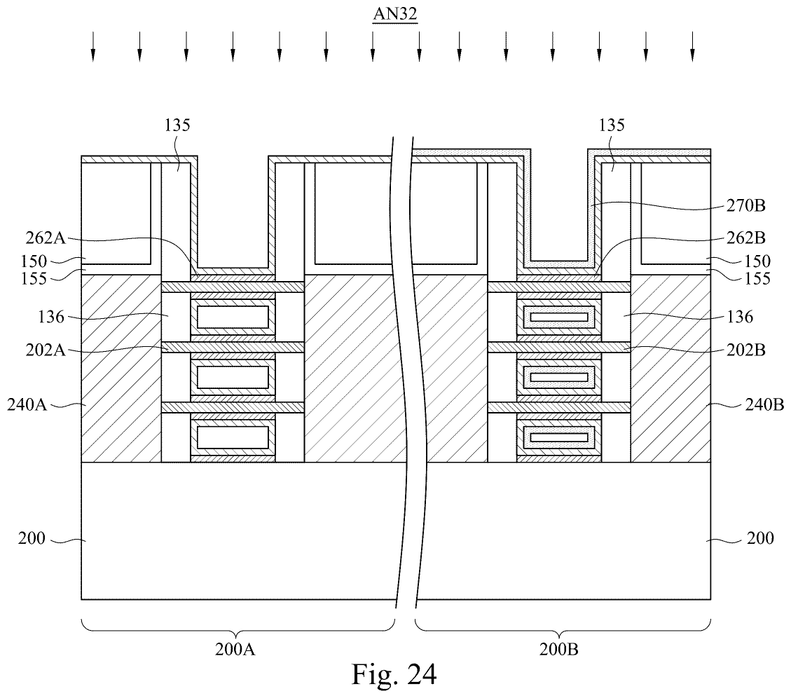

Reference is made to FIG. 24. After the annealing process AN31 is complete, the dipole layer 270A is removed. Then, a dipole layer 270B is formed over the high-k dielectric layer 264B. In some embodiments, the dipole layer 270B can be formed by, for example, forming a patterned mask (not shown) covering the region 200A of the substrate 200 and exposing the region 200B of the substrate 200, depositing the dipole layer 270B over the high-k dielectric layer 264B, and then removing the patterned mask. As a result, once the dipole layer 270B is formed, the surface of the high-k dielectric layer 264A is free of coverage by a dipole material.

In some embodiments, the dipole layers 270A and 270B may include a same material. For example, when the source/drain epitaxial structures 240A and 240B are both N-type epitaxial structures, the dipole material of the dipole layer 270B may be indium oxide (InO). On the other hand, when the source/drain epitaxial structures 240A and 240B are both P-type epitaxial structures, the dipole material of the dipole layer 270B may be aluminum oxide (AlO). Moreover, the dipole layers 270A and 270B may include substantially a same thickness. That is, the deposition conditions of the dipole layers 270A and 270B may be substantially the same.

After the dipole layer 270B is formed, an annealing process AN32 may be performed to drive the metal atoms of the dipole layer 270B into the high-k dielectric layer 264B. It is noted that, during the annealing process AN32, the surface of the high-k dielectric layer 264A is free of coverage by a dipole material, and thus no metal atoms are driven into the high-k dielectric layer 264A. The difference between the annealing process AN31 of FIG. 23 and the annealing process AN32 of FIG. 24 is that the duration of the annealing process AN32 is longer than the duration of the annealing process AN31. As a result, although the dipole layers 270A and 270B may include a same thickness and a same material, the annealing process AN32 with longer duration may drive more metal atoms into the high-k dielectric layer 264B.

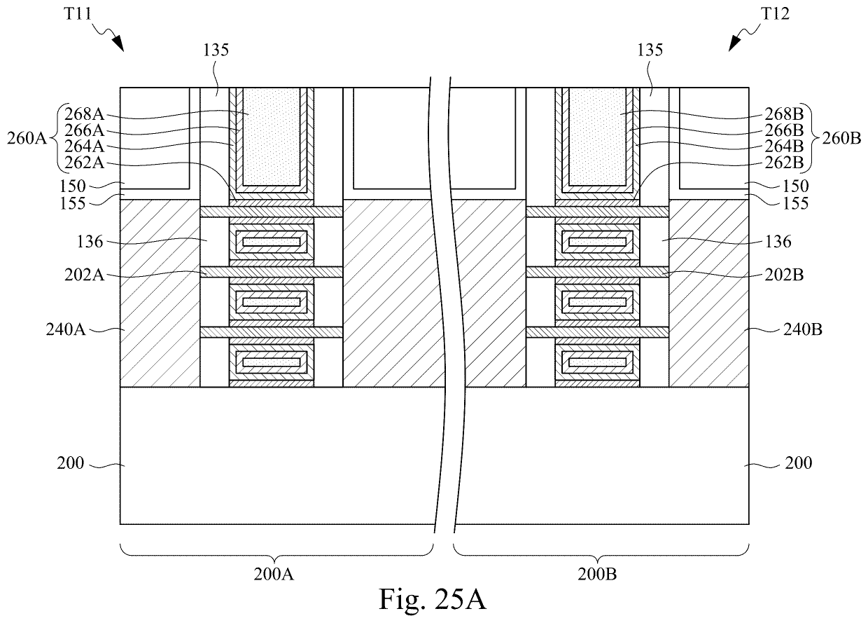

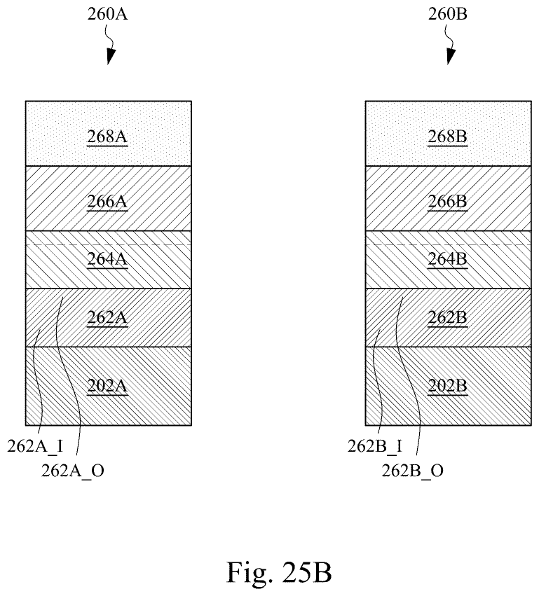

Reference is made to FIGS. 25A and 25B. After the annealing process AN32 is complete, the dipole layer 270B is removed. Then, work function metal layers 266A and 266B are formed over the high-k dielectric layers 264A and 264B, respectively. Filling metals 268A and 268B are formed over the work function metal layers 266A and 266B, respectively. As a result, metal gate structures 260A and 260B are formed. The metal gate structure 260A, the semiconductor layer 202A, and the source/drain epitaxial structures 240A may collective serve as a first transistor, and metal gate structure 260B, the semiconductor layer 202B, and the source/drain epitaxial structures 240B may collective serve as a second transistor.

FIG. 25B is a schematic view showing the metal gate structures 260A and 260B. With respect to the metal gate structure 260A, the outer region 264A_O of the high-k dielectric layer 264A of the metal gate structure 260A includes a higher concentration of metal atoms than the inner region 264A_I of the high-k dielectric layer 264A of the metal gate structure 260A. With respect to the metal gate structure 260B, the outer region 264B_O of the high-k dielectric layer 264B of the metal gate structure 260B includes a higher concentration of metal atoms than the inner region 264B_I of the high-k dielectric layer 264B of the metal gate structure 260B. However, due to the longer duration of the annealing process AN32 as discussed above, the outer region 264B_O of the high-k dielectric layer 264B may include a higher metal concentration than the outer region 264A_O of the high-k dielectric layer 264B. It is noted that the metal atom distributions in the metal gate structures 260A and 260B may be similar to those illustrated in FIG. 19.

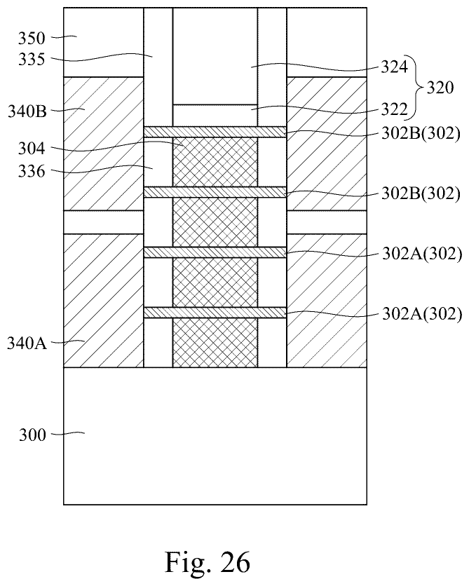

FIGS. 26 to 31C show cross-sectional views of intermediate structures at respective stages during an example method for forming a semiconductor device in accordance with some embodiments. It is noted that some elements of FIGS. 26 to 31C and the formation method thereof may be similar to those described above, and thus relevant details will not be repeated for brevity.

Reference is made to FIG. 26. Shown there is a substrate 300. A stack of alternating semiconductor layers 302 and sacrificial layers 304 are formed over the substrate 300. In some embodiments, the semiconductor layers 302 may include semiconductor layers 302A at lower level, and semiconductor layers 302B at upper level. It is understood that the number of the semiconductor layers 302A and 302B is merely used to explain, and the disclosure is not limited thereto.

A dummy gate structure 320 is formed over the stack of stack of alternating semiconductor layers 302 and sacrificial layers 304. The dummy gate structure 320 may include a dummy gate dielectric 322 and a dummy gate electrode 324 over the dummy gate dielectric 322. Gate spacers 335 are formed on opposite sidewalls of the dummy gate structure 320. Inner spacers 336 are on opposite sides of the sacrificial layers 304. Source/drain epitaxial structures 340A are on opposite sides of the dummy gate structure 320 and in contact with opposite ends of each of the semiconductor layers 302A. Source/drain epitaxial structures 340B are on opposite sides of the dummy gate structure 320 and in contact with opposite ends of each of the semiconductor layers 302B.

In some embodiments, the source/drain epitaxial structures 340A may include opposite conductivity type than the source/drain epitaxial structures 340B. For example, if the source/drain epitaxial structures 340A are N-type epitaxial structures, the source/drain epitaxial structures 340B are P-type epitaxial structures. Similarly, if the source/drain epitaxial structures 340A are P-type epitaxial structures, the source/drain epitaxial structures 340B are N-type epitaxial structures.

An interlayer dielectric (ILD) layer 250 is formed over the source/drain epitaxial structures 340A and 340B, and laterally surrounds the dummy gate structure 320. In some embodiments, portions of the ILD layer 250 may extend to spaces vertically between the source/drain epitaxial structures 340A and the source/drain epitaxial structures 340B, so as to electrically isolate the source/drain epitaxial structures 340A from the source/drain epitaxial structures 340B.

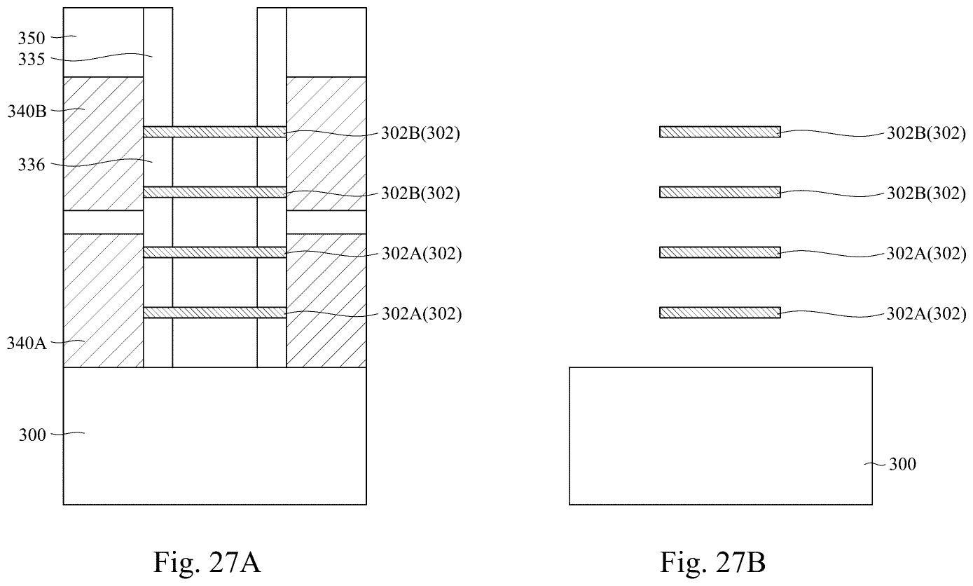

Reference is made to FIGS. 27A and 27B. The dummy gate structure 320 is removed, so as to form a gate trench between the gate spacers 335. Afterwards, the sacrificial layers 302 are removed through the gate trench, such that the semiconductor layers 302 are suspended over the substrate 100. In some embodiments, the dummy gate structure 320 and the sacrificial layers 304 can be removed using suitable etching process, such as dry etch, wet etch, or combination thereof.

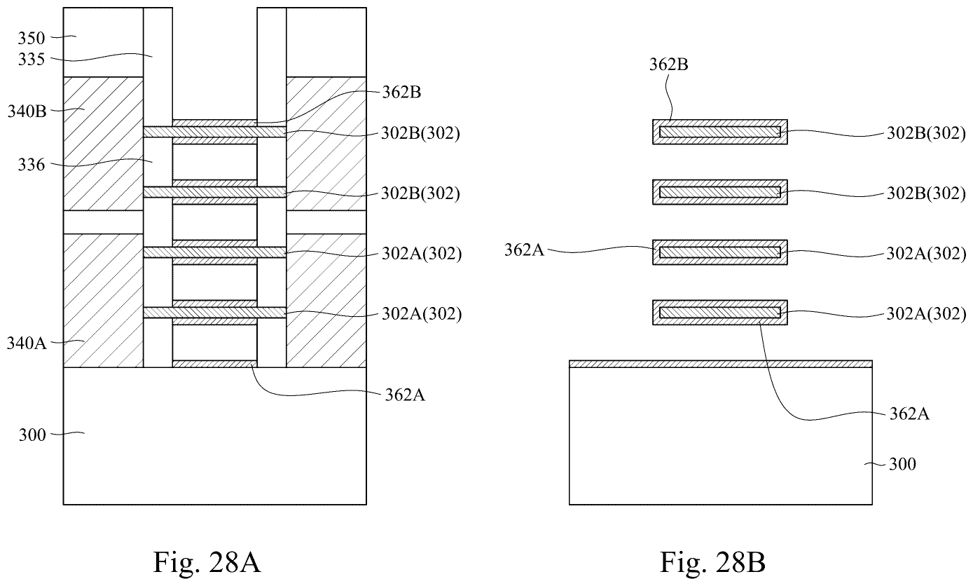

Reference is made to FIGS. 28A and 28B. Interfacial layers 362A and 362B are formed on the exposed surfaces of the semiconductor layers 302A and 302B, respectively. In some embodiments, the interfacial layers 362A and 362B may be made of a same material, such as silicon oxide (SiO₂), or the like, and may be formed using a same deposition process, such as a thermal oxidation process.

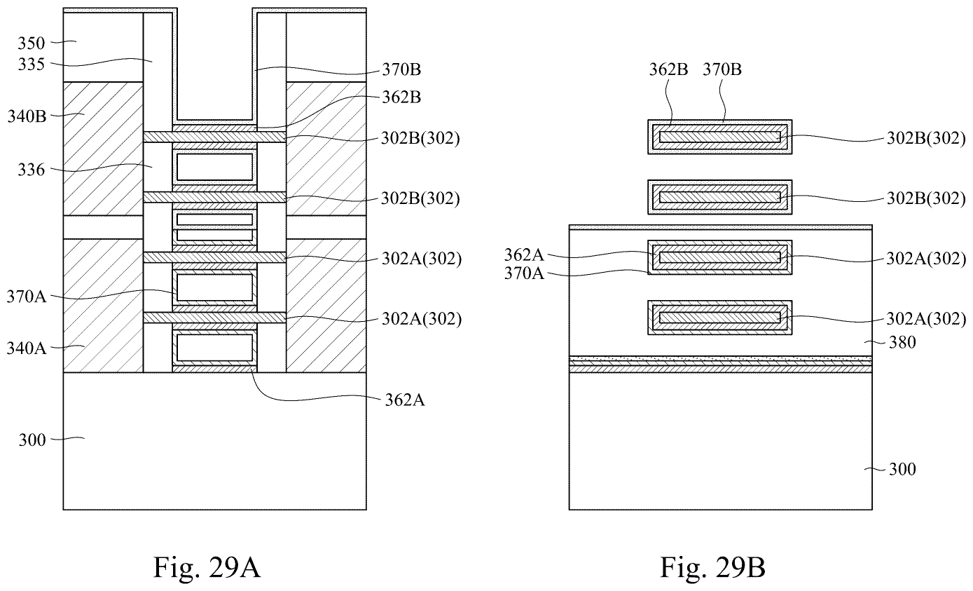

Reference is made to FIGS. 29A and 29B. Dipole layer 370A is formed on the exposed surface of the interfacial layer 362A, and dipole layer 370B is formed on the exposed surface of the interfacial layer 362B, respectively. In some embodiments, the dipole layers 370A and 370B may be made of different materials. For example, if the source/drain epitaxial structures 340A and 340B are N-type and P-type epitaxial structures, respectively, the dipole layers 370A and 370B may be indium oxide (InO) and aluminum oxide (AlO), respectively. Similarly, if the source/drain epitaxial structures 340A and 340B are P-type and N-type epitaxial structures, respectively, the dipole layers 370A and 370B may be aluminum oxide (AlO) and indium oxide (InO), respectively.

In some embodiments, the dipole layers 370A and 370B may be formed by, for example, depositing the dipole layer 370A wrapping around each of the semiconductor layers 302A and 302B and the interfacial layers 362A and 362B. A dummy material 380, which may include a dielectric material, is deposited in the gate trench. The dummy material 380 is then etched back, such that the top surface of the etched dummy material 380 is lower to a position higher than the topmost semiconductor layer 302A and lower than the bottommost semiconductor layer 302B. After the etching back process, portions of the dipole layer 370A covering the semiconductor layers 302B may be exposed. Then, the portions of the dipole layer 370A covering the semiconductor layers 302B is removed, so as to expose the interfacial layer 362B. Afterwards, the dipole layer 370B is formed over the interfacial layer 362B and wrapping around the semiconductor layers 302B. In some embodiments, the dipole layer 370B may also extend to the top surface of the dummy material 380.

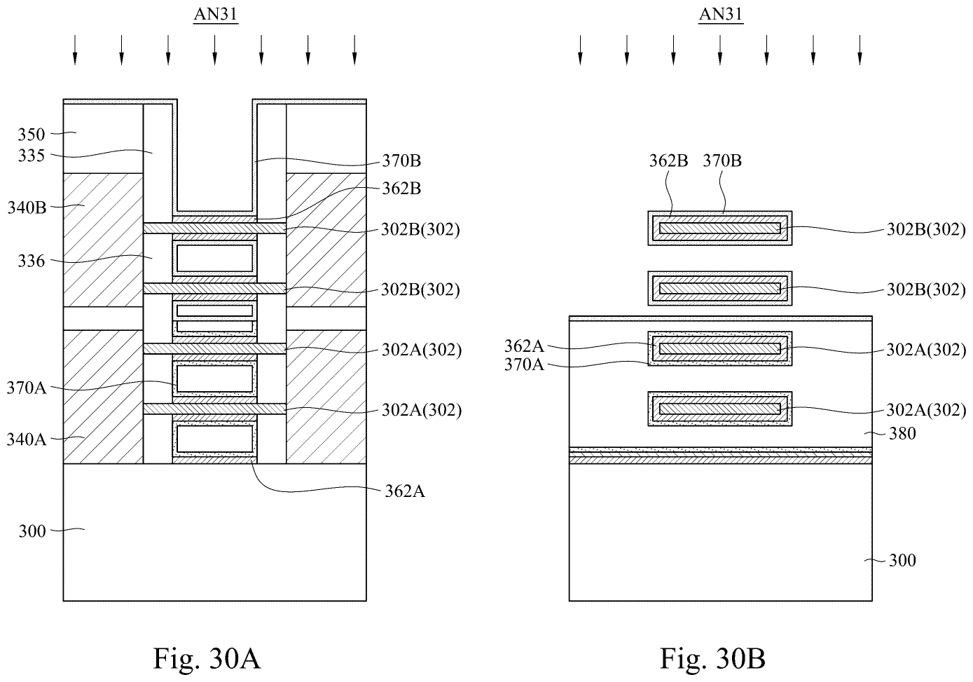

Reference is made to FIGS. 30A and 30B. After the dipole layers 370A and 370B are formed, an annealing process AN31 may be performed to drive the metal atoms of the dipole layers 370A and 370B into the interfacial layers 362A and 362B, respectively.

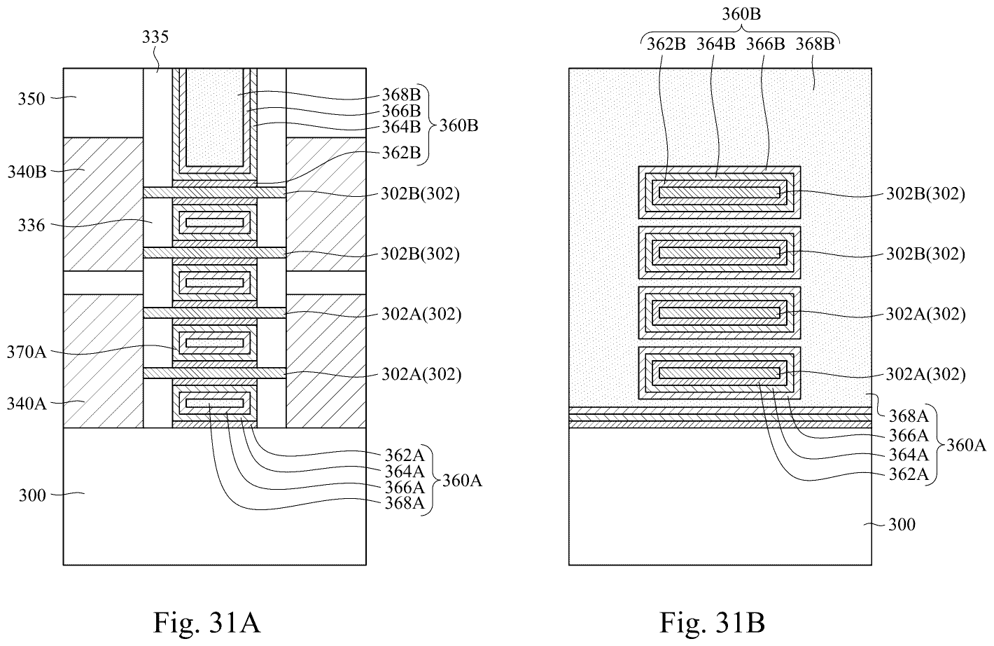

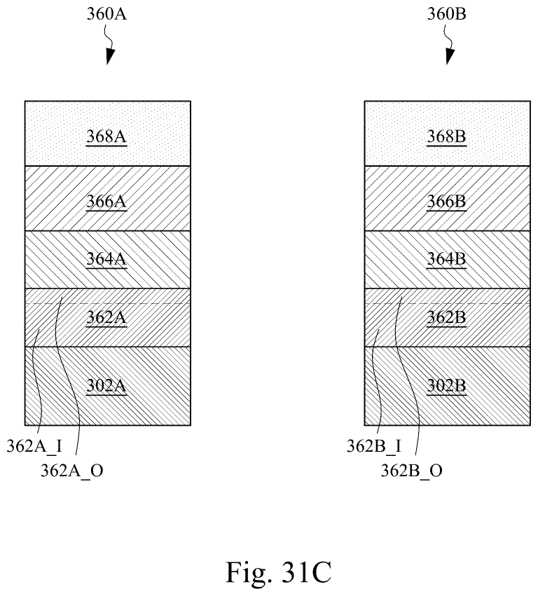

Reference is made to FIGS. 31A to 31C. After the annealing process AN31 is complete, the dipole layers 370A and 370B and the dummy material 380 are removed. Then, high-k dielectric layers 364A and 364B are formed over the interfacial layers 362A and 362B, respectively. Work function metal layers 366A and 366B are formed over the high-k dielectric layers 364A and 364B, respectively. Filling metals 368A and 368B are formed over the work function metal layers 366A and 366B, respectively. As a result, metal gate structures 360A and 360B are formed. The metal gate structure 360A, the semiconductor layer 302A, and the source/drain epitaxial structures 340A may collective serve as a first transistor, and metal gate structure 360B, the semiconductor layer 302B, and the source/drain epitaxial structures 340B may collective serve as a second transistor vertically stacked over the first transistor. It is understood that the high-k dielectric layers 364A and 364B may include a same material and may be formed at the same time. The work function metal layers 366A and 366B may include a same material and may be formed at the same time. The filling metals 368A and 368B a may include a same material and may be formed at the same time. In some embodiments, the filling metals 368A and 368B are in contact with each other.

FIG. 31C is a schematic view showing the metal gate structures 360A and 360B. With respect to the metal gate structure 360A, the outer region 362A_O of the interfacial layer 362A of the metal gate structure 360A includes a higher concentration of first metal atoms than the inner region 362A_I of the interfacial layer 362A of the metal gate structure 360A. With respect to the metal gate structure 360B, the outer region 362B_O of the interfacial layer 362B of the metal gate structure 360B includes a higher concentration of second metal atoms than the inner region 362B_I of the interfacial layer 362B of the metal gate structure 360B. In some embodiments, the first metal atoms are different from the second metal atoms.

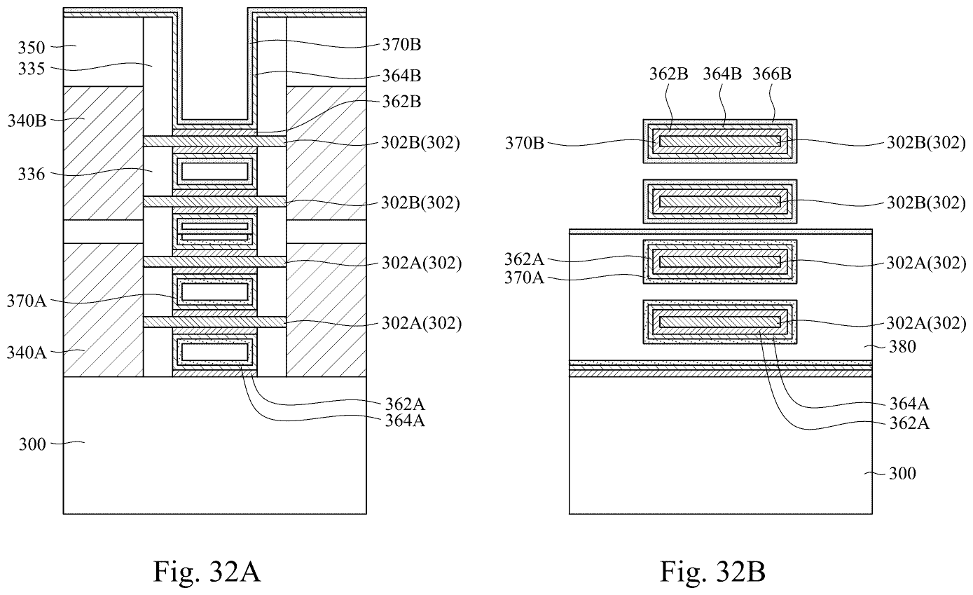

FIGS. 32A to 34C show cross-sectional views of intermediate structures at respective stages during an example method for forming a semiconductor device in accordance with some embodiments. It is noted that some elements of FIGS. 32A to 34C and the formation method thereof may be similar to those described above, and thus relevant details will not be repeated for brevity.

Reference is made to FIGS. 32A and 32B. A deposition process is performed for forming a high-k dielectric material over the structure shown in FIGS. 27A and 27B. As a result, high-k dielectric layers 364A and 364B are formed over the interfacial layers 362A and 362B, respectively.

Then, dipole layer 370A is formed on the exposed surface of the high-k dielectric layer 364A, and dipole layer 370B is formed on the exposed surfaces of the high-k dielectric layer 364B, respectively. In some embodiments, the dipole layers 370A and 370B may be made of different materials. For example, if the source/drain epitaxial structures 340A and 340B are N-type and P-type epitaxial structures, respectively, the dipole layers 370A and 370B may be indium oxide (InO) and aluminum oxide (AlO), respectively. Similarly, if the source/drain epitaxial structures 340A and 340B are P-type and N-type epitaxial structures, respectively, the dipole layers 370A and 370B may be aluminum oxide (AlO) and indium oxide (InO), respectively.

In some embodiments, the dipole layers 370A and 370B may be formed by, for example, depositing the dipole layer 370A wrapping around each of the semiconductor layers 302A and 302B and the interfacial layers 362A and 362B. A dummy material 380, which may include a dielectric material, is deposited in the gate trench. The dummy material 380 is then etched back, such that the top surface of the etched dummy material 380 is lower to a position higher than the topmost semiconductor layer 302A and lower than the bottommost semiconductor layer 302B. After the etching back process, portions of the dipole layer 370A covering the semiconductor layers 302B may be exposed. Then, the portions of the dipole layer 370A covering the semiconductor layers 302B is removed, so as to expose the high-k dielectric layer 364B. Afterwards, the dipole layer 370B is formed over the high-k dielectric layer 364B and wrapping around the semiconductor layers 302B. In some embodiments, the dipole layer 370B may also extend to the top surface of the dummy material 380.

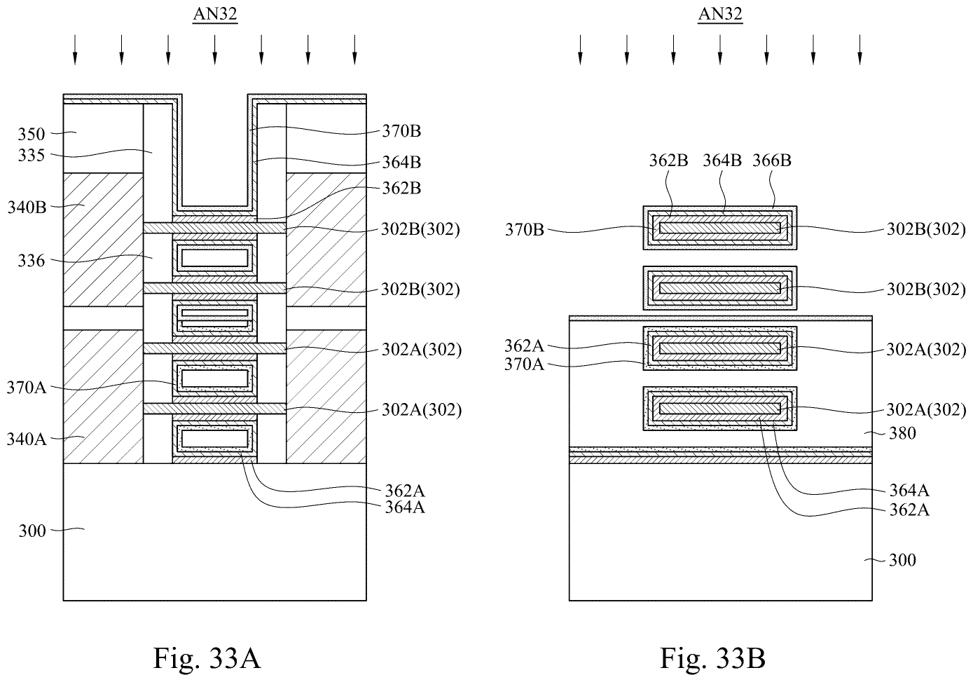

Reference is made to FIGS. 33A and 33B. After the dipole layers 370A and 370B are formed, an annealing process AN32 may be performed to drive the metal atoms of the dipole layers 370A and 370B into the high-k dielectric layers 364A and 364B, respectively.

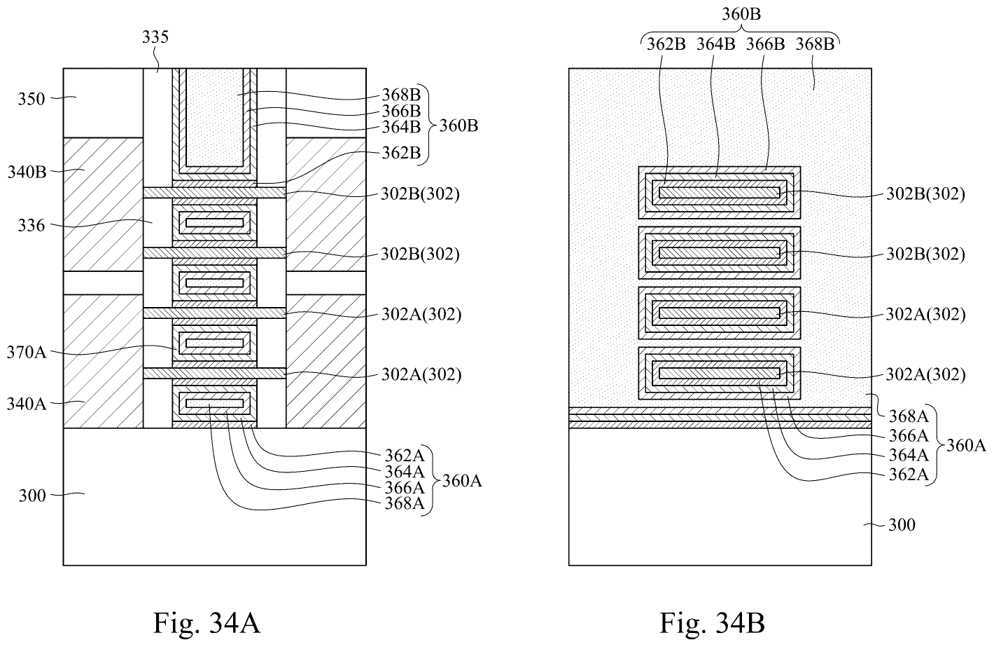

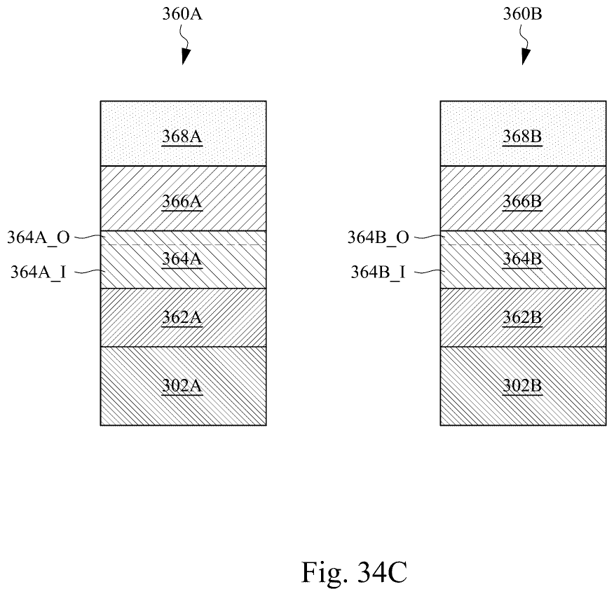

Reference is made to FIGS. 34A to 34C. After the annealing process AN32 is complete, the dipole layers 370A and 370B and the dummy material 380 are removed. Then, work function metal layers 366A and 366B are formed over the high-k dielectric layers 364A and 364B, respectively. Filling metals 368A and 368B are formed over the work function metal layers 366A and 366B, respectively. As a result, metal gate structures 360A and 360B are formed. The metal gate structure 360A, the semiconductor layer 302A, and the source/drain epitaxial structures 340A may collective serve as a first transistor, and metal gate structure 360B, the semiconductor layer 302B, and the source/drain epitaxial structures 340B may collective serve as a second transistor. It is understood that the high-k dielectric layers 364A and 364B may include a same material and may be formed at the same time. The work function metal layers 366A and 366B may include a same material and may be formed at the same time. The filling metals 368A and 368B a may include a same material and may be formed at the same time. In some embodiments, the filling metals 368A and 368B are in contact with each other.

FIG. 34C is a schematic view showing the metal gate structures 360A and 360B. With respect to the metal gate structure 360A, the outer region 364A_O of the high-k dielectric layer 364A of the metal gate structure 360A includes a higher concentration of first metal atoms than the inner region 364A_I of the high-k dielectric layer 364A of the metal gate structure 360A. With respect to the metal gate structure 360B, the outer region 364B_O of the high-k dielectric layer 364B of the metal gate structure 360B includes a higher concentration of second metal atoms than the inner region 364B_I of the high-k dielectric layer 364B of the metal gate structure 360B. In some embodiments, the first metal atoms are different from the second metal atoms.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a method for forming a multi-threshold voltage device. Different dipole layers are formed on different layers of gate structures. One or more annealing processes may be conducted to drive the metal atoms of the dipole layers into the corresponding layers of the gate structures for tuning the threshold voltage of the devices. The dipole layers may be removed after the annealing processes to create larger process window for the following formed work function metal layers and filling metals, which is helpful for forming seamless or void-free devices. With such configuration, the device performance may be improved.

In some embodiments of the present disclosure, a semiconductor device includes a substrate, a first transistor over a first region of the substrate, and a second transistor over a second region of the substrate. The first transistor includes first semiconductor channel layers and a first gate structure wrapping around each of the first semiconductor channel layers. The first gate structure includes a first interfacial layer, a first high-k dielectric layer over the first interfacial layer, and a first filling metal over the first high-k dielectric layer. A region of the first interfacial layer close to the first high-k dielectric layer has a higher concentration of a first metal element than a region of the first interfacial layer away from the first high-k dielectric layer. The second transistor has a same conductivity type as the first transistor. The second transistor includes second semiconductor channel layers and a second gate structure wrapping around each of the second semiconductor channel layers. The second gate structure includes a second interfacial layer, a second high-k dielectric layer over the second interfacial layer, a second filling metal over the second high-k dielectric layer. A region of the second high-k dielectric layer close to the second filling metal has a higher concentration of the first metal element than a region of the second high-k dielectric layer away from the second filling metal.

In some embodiments, the first transistor and the second transistor are N-type transistors, and the first metal element is indium (In).

In some embodiments, the first transistor and the second transistor are P-type transistors, and the first metal element is aluminum (Al).

In some embodiments, the first high-k dielectric layer and the second high-k dielectric layer are free of the first metal element.

In some embodiments, the first transistor and the second transistor have different threshold voltages.

In some embodiments, the semiconductor device further includes a third transistor over a third region of the substrate and having an opposite conductivity type than the first transistor. The third transistor includes third semiconductor channel layers and a third gate structure wrapping around each of the third semiconductor channel layers. The third gate structure includes a third interfacial layer, a third high-k dielectric layer over the third interfacial layer, and a third filling metal over the third high-k dielectric layer. A region of the third interfacial layer close to the third high-k dielectric layer has a higher concentration of a second metal element than a region of the third interfacial layer away from the third high-k dielectric layer, and the first metal element is different from the second metal element.

In some embodiments, the semiconductor device further includes a fourth transistor over a fourth region of the substrate and having an opposite conductivity type than the first transistor. The fourth transistor includes fourth semiconductor channel layers and a fourth gate structure wrapping around each of the fourth semiconductor channel layers. The fourth gate structure includes a fourth interfacial layer, a fourth high-k dielectric layer over the fourth interfacial layer, and a fourth filling metal over the fourth high-k dielectric layer. A region of the fourth high-k dielectric layer close to the fourth filling metal has a higher concentration of the second metal element than a region of the fourth high-k dielectric layer away from the fourth filling metal.

In some embodiments, the semiconductor device further includes a fifth transistor over a fifth region of the substrate. The fifth transistor includes fifth semiconductor channel layers and a fifth gate structure wrapping around each of the fifth semiconductor channel layers. The fifth gate structure includes a fifth interfacial layer, a fifth high-k dielectric layer over the fifth interfacial layer, and a fifth filling metal over the fifth high-k dielectric layer. The fifth interfacial layer is free of the first metal element and the second metal element. The fifth high-k dielectric layer is free of the first metal element and the second metal element.

In some embodiments of the present disclosure, a semiconductor device includes a substrate, a first transistor over the substrate, and a second transistor over the substrate. The first transistor includes first semiconductor channel layers and a first gate structure wrapping around each of the first semiconductor channel layers. The first gate structure includes a first interfacial layer, a first high-k dielectric layer over the first interfacial layer, and a first filling metal over the first high-k dielectric layer. A first metal element is detectable in the first interfacial layer or the first high-k dielectric layer. The second transistor includes second semiconductor channel layers and a second gate structure wrapping around each of the second semiconductor channel layers. The second gate structure includes a second interfacial layer, a second high-k dielectric layer over the second interfacial layer, and a second filling metal over the second high-k dielectric layer. A second metal element different from the first metal element is detectable in the second interfacial layer or the second high-k dielectric layer.

In some embodiments, the first transistor is stacked vertically above the second transistor.

In some embodiments, the first filling metal and the second filling metal are made of a same material and are in contact with each other.

In some embodiments, the first metal element is detectable in the first interfacial layer and the second metal element is detectable in the second interfacial layer.

In some embodiments, the first metal element is detectable in the first high-k dielectric layer and the second metal element is detectable in the second high-k dielectric layer.

In some embodiments, one of the first and second metal elements is indium (In) and another one of the first and second metal elements is aluminum (Al).

In some embodiments, the first transistor and the second transistor have opposite conductivity types.

In some embodiments of the present disclosure, a method includes forming first semiconductor channel layers and second semiconductor channel layers over a substrate; forming a first interfacial layer over the first semiconductor channel layers and a second interfacial layer over the second semiconductor channel layers, respectively; forming a first dipole layer over the first interfacial layer and forming a second dipole layer over the second interfacial layer, respectively; performing an annealing process; removing the first dipole layer and the second dipole layer after the annealing process is complete; forming a first high-k dielectric layer over the first interfacial layer and a second high-k dielectric layer over the second interfacial layer, respectively; and forming a first filling metal over the first high-k dielectric layer and a second filling metal over the second high-k dielectric layer, respectively.

In some embodiments, the first dipole layer and the second dipole layer are made of different materials.

In some embodiments, the first dipole layer and the second dipole layer are made of a same material.

In some embodiments, the first dipole layer and the second dipole layer have different thicknesses.

In some embodiments, the second semiconductor channel layers are vertically above the first semiconductor channel layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a first transistor over a first region of the substrate, the first transistor comprising first semiconductor channel layers and a first gate structure wrapping around each of the first semiconductor channel layers, wherein the first gate structure comprises:
a first interfacial layer;
a first high-k dielectric layer over the first interfacial layer, wherein a region of the first interfacial layer close to the first high-k dielectric layer has a higher concentration of a first metal element than a region of the first interfacial layer away from the first high-k dielectric layer; and
a first filling metal over the first high-k dielectric layer; and
a second transistor over a second region of the substrate and having a same conductivity type as the first transistor, the second transistor comprising second semiconductor channel layers and a second gate structure wrapping around each of the second semiconductor channel layers, wherein the second gate structure comprises:
a second interfacial layer;
a second high-k dielectric layer over the second interfacial layer; and
a second filling metal over the second high-k dielectric layer, wherein a region of the second high-k dielectric layer close to the second filling metal has a higher concentration of the first metal element than a region of the second high-k dielectric layer away from the second filling metal.

2. The semiconductor device of claim 1, wherein the first transistor and the second transistor are N-type transistors, and the first metal element is indium (In).

3. The semiconductor device of claim 1, wherein the first transistor and the second transistor are P-type transistors, and the first metal element is aluminum (Al).

4. The semiconductor device of claim 1, wherein the first high-k dielectric layer and the second high-k dielectric layer are free of the first metal element.

5. The semiconductor device of claim 1, wherein the first transistor and the second transistor have different threshold voltages.

6. The semiconductor device of claim 1, further comprising:
a third transistor over a third region of the substrate and having an opposite conductivity type than the first transistor, the third transistor comprising third semiconductor channel layers and a third gate structure wrapping around each of the third semiconductor channel layers, wherein the third gate structure comprises:
a third interfacial layer;
a third high-k dielectric layer over the third interfacial layer, wherein a region of the third interfacial layer close to the third high-k dielectric layer has a higher concentration of a second metal element than a region of the third interfacial layer away from the third high-k dielectric layer, and wherein the first metal element is different from the second metal element; and
a third filling metal over the third high-k dielectric layer.

7. The semiconductor device of claim 6, further comprising:
a fourth transistor over a fourth region of the substrate and having an opposite conductivity type than the first transistor, the fourth transistor comprising fourth semiconductor channel layers and a fourth gate structure wrapping around each of the fourth semiconductor channel layers, wherein the fourth gate structure comprises:
a fourth interfacial layer;
a fourth high-k dielectric layer over the fourth interfacial layer; and
a fourth filling metal over the fourth high-k dielectric layer, wherein a region of the fourth high-k dielectric layer close to the fourth filling metal has a higher concentration of the second metal element than a region of the fourth high-k dielectric layer away from the fourth filling metal.

8. The semiconductor device of claim 7, further comprising:
a fifth transistor over a fifth region of the substrate, the fifth transistor comprising fifth semiconductor channel layers and a fifth gate structure wrapping around each of the fifth semiconductor channel layers, wherein the fifth gate structure comprises:
a fifth interfacial layer, wherein the fifth interfacial layer is free of the first metal element and the second metal element;
a fifth high-k dielectric layer over the fifth interfacial layer, wherein the fifth high-k dielectric layer is free of the first metal element and the second metal element; and
a fifth filling metal over the fifth high-k dielectric layer.

9. A semiconductor device, comprising:
a substrate;
a first transistor over the substrate, the first transistor comprising first semiconductor channel layers and a first gate structure wrapping around each of the first semiconductor channel layers, wherein the first gate structure comprises:
a first interfacial layer;
a first high-k dielectric layer over the first interfacial layer, wherein a first metal element is detectable in the first interfacial layer or the first high-k dielectric layer; and
a first filling metal over the first high-k dielectric layer; and
a second transistor over the substrate, the second transistor comprising second semiconductor channel layers and a second gate structure wrapping around each of the second semiconductor channel layers, wherein the second gate structure comprises:
a second interfacial layer;
a second high-k dielectric layer over the second interfacial layer, wherein a second metal element different from the first metal element is detectable in the second interfacial layer or the second high-k dielectric layer; and
a second filling metal over the second high-k dielectric layer.

10. The semiconductor device of claim 9, wherein the first transistor is stacked vertically above the second transistor.

11. The semiconductor device of claim 9, wherein the first filling metal and the second filling metal are made of a same material and are in contact with each other.

12. The semiconductor device of claim 9, wherein the first metal element is detectable in the first interfacial layer and the second metal element is detectable in the second interfacial layer.

13. The semiconductor device of claim 9, wherein the first metal element is detectable in the first high-k dielectric layer and the second metal element is detectable in the second high-k dielectric layer.

14. The semiconductor device of claim 9, wherein one of the first and second metal elements is indium (In) and another one of the first and second metal elements is aluminum (Al).

15. The semiconductor device of claim 9, wherein the first transistor and the second transistor have opposite conductivity types.

16. A method, comprising:
forming first semiconductor channel layers and second semiconductor channel layers over a substrate;
forming a first interfacial layer over the first semiconductor channel layers and a second interfacial layer over the second semiconductor channel layers, respectively;
forming a first dipole layer over the first interfacial layer and forming a second dipole layer over the second interfacial layer, respectively;
performing an annealing process;
removing the first dipole layer and the second dipole layer after the annealing process is complete;
forming a first high-k dielectric layer over the first interfacial layer and a second high-k dielectric layer over the second interfacial layer, respectively; and
forming a first filling metal over the first high-k dielectric layer and a second filling metal over the second high-k dielectric layer, respectively.

17. The method of claim 16, wherein the first dipole layer and the second dipole layer are made of different materials.

18. The method of claim 16, wherein the first dipole layer and the second dipole layer are made of a same material.

19. The method of claim 18, wherein the first dipole layer and the second dipole layer have different thicknesses.

20. The method of claim 16, wherein the second semiconductor channel layers are vertically above the first semiconductor channel layers.
